(19) United States
(12) Patent Application Publication
(10) Pub. No.: US 2016/0049487 A1
(43) Pub. Date: Feb. 18, 2016

(54) DEVICE INCLUDING CAVITY AND SELF-ALIGNED CONTACT AND METHOD OF FABRICATING THE SAME

(71) Applicant: QUALCOMM Incorporated, San Diego, CA (US)

(72) Inventors: Jeffrey Junhao Xu, San Diego, CA (US); John Jianhong Zhu, San Diego, CA (US); Vladimir Machkaoutsan, Leuven (BE); Mustafa Badaroglu, Leuven (BE); Choh Fei Yeap, San Diego, CA (US)

(21) Appl. No.: 14/670,268

(22) Filed: Mar. 26, 2015

Related U.S. Application Data
(60) Provisional application No. 62/037,898, filed on Aug. 15, 2014.

(51) Int. Cl. H01L 29/423; H01L 29/66; H01L 29/78

(52) U.S. Cl. CPC H01L 29/42364; H01L 29/785; H01L 29/66795; H01L 29/6653

(57) ABSTRACT

A device includes a first structure and a second structure. The second structure is separated from the first structure by a cavity. The device further includes a seal material, an etch stop material defining an etched region, and a self-aligned contact (SAC). The seal material is configured to seal the cavity, and the SAC is formed within the etched region. The SAC adjoins the seal material, the etch stop material, or a combination thereof.

### I. CROSS-REFERENCE TO RELATED APPLICATION

The present application claims the benefit of U.S. Provisional Patent Application No. 62/037,898, filed Aug. 15, 2014 and entitled “DEVICE INCLUDING CAVITY AND SELF-ALIGNED CONTACT AND METHOD OF FABRICATING THE SAME,” the content of which is incorporated by reference herein in its entirety.

### II. FIELD

This disclosure is generally related to devices, such as electronic devices.

### III. DESCRIPTION OF RELATED ART

Advances in technology have resulted in smaller and more powerful electronic devices. For example, mobile devices and other electronic devices may be small, lightweight, and easily carried by users. A mobile device may perform a variety of processing and communication operations, such as communicating voice and data information over a communication network.

To enable mobile devices and other electronic devices to perform such operations while maintaining a small device size, integrated circuits and other device components have been scaled. For example, sizes of transistors and other electronic components of the integrated circuits have been reduced. As component sizes are reduced, performance of an integrated circuit can be affected or impaired. To illustrate, as more electronic components are integrated within a particular circuit area, a “stray” electric field generated by a component may begin to significantly alter operation of another component. In this case, operation of an integrated circuit may deviate from design parameters of the integrated circuit, which may cause poor performance or malfunction of the integrated circuit.

### IV. SUMMARY

Parasitic capacitance of a device is reduced using a cavity, such as an air spacer or a vacuum spacer. The cavity may be adjacent to a gate structure of the device and may be sealed with a seal material. Because the cavity has a lower dielectric parameter (k) than certain other spacer materials (e.g., silicon nitride), gate capacitance of the device is reduced, which may improve device performance. For example, performance of the device in response to alternating current (AC) signals may be improved by reducing capacitive charging and discharging of the device.

In addition, a self-aligned contact (SAC) may be formed in an etched region that is positioned above the cavity. An etch process used to define the etched region may use a carbon-doped (C-doped) nitride etch stop layer (NESL) that resists certain etch processes (i.e., etch selectivity). Due to etch selectivity of the NESL, “punch-through” to the cavity may be avoided. For example, if the etch process selectively etches the NESL but not the seal material or oxide materials, misalignment of the etch process (e.g., etching too far) does not result in punch-through to the cavity. Accordingly, the SAC can be formed near the cavity (e.g., to connect the gate structure to other device components) without risking electrical shorts and other effects caused by punch-through.

In a particular example, a device includes a first structure and a second structure. The second structure is separated from the first structure by a cavity. The device further includes a seal material, an etch stop material defining an etched region, and a self-aligned contact (SAC). The seal material is configured to seal the cavity, and the SAC is formed within the etched region. The SAC adjoins the seal material, the etch stop material, or a combination thereof.

In another particular example, an apparatus includes means for sealing a cavity, means for defining an etched region, and means for conducting a signal. The means for conducting the signal includes a self-aligned contact (SAC) formed within the etched region. The SAC adjoins the means for sealing the cavity, the means for defining the etched region, or a combination thereof.

In another particular example, a method of fabrication of a device includes defining a cavity and forming a seal material. The seal material adjoins the cavity. The method further includes defining an etched region by etching an etch stop material and forming a self-aligned contact (SAC) within the etched region. The SAC adjoins the seal material, the etch stop material, or a combination thereof.

One particular advantage provided by at least one of the disclosed embodiments is an improved process window for fabrication of a device. For example, use of an SAC may increase (or “relax”) a target area for an etched region in which the SAC is formed. In this case, etch process misalignment (e.g., by etching too long or too far in a direction) may not result in damage to the device. Thus, manufacturing yield may be improved. Further, lithographic overlay associated with fabrication of the device may be simplified, such as by using an etch selective process to form the etched region (instead of using complex lithographic overlays). Other aspects, advantages, and features of the present disclosure will become apparent after review of the entire application, including the following sections: Brief Description of the Drawings, Detailed Description, and the Claims.

### V. BRIEF DESCRIPTION OF THE DRAWINGS

FIG. 1 is a diagram that depicts a cross-sectional view of an illustrative example of a device that includes a cavity and a self-aligned contact (SAC), such as a source or drain SAC.

FIG. 2 is a diagram illustrating an example of a first stage of a first fabrication process to fabricate a device, such as the device of FIG. 1.

FIG. 3 is a diagram illustrating an example of a second stage of the first fabrication process.

FIG. 4 is a diagram illustrating an example of a third stage of the first fabrication process.

FIG. 5 is a diagram illustrating an example of a fourth stage of the first fabrication process.

FIG. 6 is a diagram illustrating an example of a fifth stage of the first fabrication process.

FIG. 7 is a diagram illustrating an example of a sixth stage of the first fabrication process.

FIG. 8 is a diagram illustrating an example of a seventh stage of the first fabrication process.

FIG. 9 is a diagram illustrating an example of an eighth stage of the first fabrication process.

FIG. 10 is a diagram illustrating an example of a ninth stage of the first fabrication process.

FIG. 11 is a diagram illustrating an example of a tenth stage of the first fabrication process.

FIG. 12 is a diagram illustrating an example of an eleventh stage of the first fabrication process.

FIG. 13 is a diagram illustrating an example of a twelfth stage of the first fabrication process.

FIG. 14A is a diagram illustrating an example of a thirteenth stage of the first fabrication process.

FIG. 14B is a diagram illustrating another view of the thirteenth stage of the first fabrication process.

FIG. 15 is a diagram illustrating an example of a fourteenth stage of the first fabrication process.

FIG. 16 is a diagram illustrating an example of a fifteenth stage of the first fabrication process.

FIG. 17 is a diagram illustrating an example of a sixteenth stage of the first fabrication process.

FIG. 18 is a diagram illustrating an example of a seventeenth stage of the first fabrication process.

FIG. 19 is a diagram illustrating an example of an eighteenth stage of the first fabrication process, which may correspond to a perspective view of the device of FIG. 1.

FIG. 20 is a diagram that depicts a cross-sectional view of an illustrative example of another device that includes a cavity and an SAC, such as a butted SAC.

FIG. 21 is a diagram illustrating an example of a first stage of a second fabrication process to fabricate a device, such as the device of FIG. 20.

FIG. 22 is a diagram illustrating an example of a second stage of the second fabrication process.

FIG. 23 is a diagram illustrating an example of a third stage of the second fabrication process, which may correspond to a perspective view of the device of FIG. 20.

FIG. 24 is a diagram that depicts a cross-sectional view of an illustrative example of another device that includes a cavity and an SAC, such as a gate SAC.

FIG. 25 is a diagram illustrating an example of a first stage of a third fabrication process to fabricate a device, such as the device of FIG. 24.

FIG. 26 is a diagram illustrating an example of a second stage of the third fabrication process.

FIG. 27 is a diagram illustrating an example of a third stage of the third fabrication process, which may correspond to a perspective view of the device of FIG. 24.

FIG. 28 is a flow diagram that depicts an illustrative method of operation of a device that includes a cavity and an SAC.

FIG. 29 is a flow diagram that depicts an illustrative method of fabrication of a device that includes a cavity and an SAC.

FIG. 30 is a block diagram of an electronic device including a device that includes a cavity and an SAC.

FIG. 31 is a data flow diagram of a particular illustrative embodiment of a manufacturing process to manufacture electronic devices that include a device including a cavity and an SAC.

### VI. DETAILED DESCRIPTION

Certain examples are described below with reference to the drawings. In the description and the drawings, similar or common features may be indicated by common reference numbers.

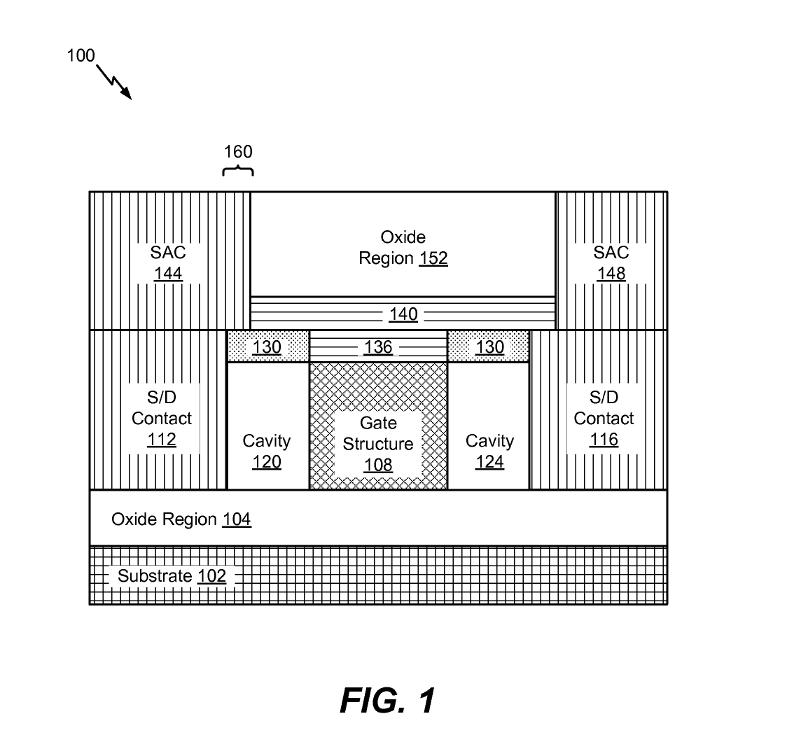

Referring to FIG. 1, a particular illustrative embodiment of a device is depicted and generally designated 100. The device 100 may be a field-effect transistor (FET) device, such as a FinFET device. An example of a FinFET device is a three-dimensional (3D) FinFET device.

The device 100 includes a substrate 102. The substrate 102 may be a semiconductor substrate or a glass substrate, as illustrative examples. An oxide region 104 may be formed on the substrate 102. For example, the device 100 may have a silicon-on-insulator (SOI) configuration in which one or more devices (e.g., a transistor) are formed on an oxide region, such as the oxide region 104. The oxide region 104 may include a silicon oxide material, as an illustrative example. In other implementations, the device 100 may have another configuration. For example, the device 100 may be fabricated using a complementary metal-oxide-semiconductor (CMOS) process that forms components directly on the substrate 102 (instead of an on oxide region). In this example, the oxide region 104 may be omitted from the device 100.

The device 100 may further include a gate structure 108. The gate structure 108 may include one or more conductive materials, such as one or more metal materials. In an illustrative implementation, the gate structure 108 is a metal gate. In this case, the device 100 may be a high-k metal gate (HKMG) device, where k indicates a dielectric parameter.

The device 100 may further include a source or drain (S/D) contact 112 and a source or drain (S/D) contact 116. In the example of FIG. 1, the gate structure 108 and the S/D contact 112 may define a cavity 120, and the gate structure 108 and the S/D contact 116 may define a cavity 124. The cavities 120, 124 may correspond to air-filled spacers or vacuum spacers.

The device 100 may further include a seal material 130. The seal material 130 may be configured to seal (or substantially seal) the cavities 120, 124. For example, the seal material 130 may be configured to seal air (or another gas) within the cavities 120, 124. In other cases, the cavities 120, 124 may correspond to vacuum spacers, and the seal material 130 may be configured to prevent or inhibit air from reaching the cavities 120, 124. The seal material 130 may include a silicon oxide material or a carbon-doped silicon oxide material, as illustrative examples. The seal material 130 may have an etch selectivity that resists some (but not all) etch processes used during fabrication of the device 100. For example, the seal material 130 may be etch selective with respect to nitride and/or oxide (so an etch process etches nitride and/or oxide more rapidly than the seal material 130). The seal material 130 may be formed using a deposition process, such as using a chemical vapor deposition (CVD) process.

The device 100 may further include an etch stop material 136 and an etch stop material 140. The etch stop materials 136, 140 may have an etch selectivity that resists some (but not all) etch processes used during fabrication of the device 100. The etch stop materials 136, 140 may include one or more carbon-doped (C-doped) materials, such as a C-doped nitride material, as an illustrative example. In this case, the etch stop materials 136, 140 may each correspond to a C-doped nitride etch stop layer (NESL). The example of FIG. 1 further depicts that an oxide region 152 may be formed on the etch stop material 140.

The device 100 may further include a self-aligned contact (SAC) 144 and an SAC 148. The SAC 144 is formed on the S/D contact 112, and the SAC 148 is formed on the S/D contact 116. The SACs 144, 148 may include one or more conductive materials, such as one or more metal materials (e.g., tungsten). The SAC 144 and the S/D contact 112 may form a two-level metal contact structure, and the SAC 148 and the S/D contact 116 may form another two-level metal contact structure. A two-level contact structure may include a single material or multiple materials.

The SACs 144, 148 may be formed within etched regions of the device 100 that are etched using a selective etch process. For example, as described further below, an etch process may create the etched regions by selectively etching one or more materials of the device 100 without substantially etching the seal material 130 and/or the S/D contacts 112, 116. As a result, the etched regions (and the SACs 144, 148) can be “misaligned” without inadvertently punching through materials of the device 100.

To further illustrate, the example of FIG. 1 depicts that the SAC 144 is “misaligned” with respect to the S/D contact 112, resulting in an overhang 160 of the SAC 144. In this case, an etch process used to define a region in which the SAC 144 is formed may have “overshot” the targeted area to be etched. In some devices, an etch process overshoot can result in punch-through, such as by punching through the seal material 130. Because an etch selective process is used to define the region in which the SAC 144 is formed, the overhang 160 does not result in punch-through. Thus, the SAC 144 is self-aligned with respect to the process used to etch the region in which the SAC 144 is formed.

After fabrication, the device 100 may be integrated within an electronic device, such as within a mobile device, as an illustrative example. During operation of the electronic device, the device 100 may be biased using bias voltages. For example, a bias voltage (or a ground voltage) may be applied at the SAC 144 to bias a source or drain region of the device 100 (not shown in FIG. 1) via the S/D contact 112. As another example, a bias voltage (or a ground voltage) may be applied at the SAC 148 to bias a source or drain region of the device 100 (not shown in FIG. 1) via the S/D contact 116. The gate structure 108 may be biased using another contact (not shown in FIG. 1), which may activate a channel between the S/D contacts 112, 116. For example, in a 3D FinFET implementation, a fin (not shown in FIG. 1) may adjoin the S/D contacts 112, 116. In this case, application of a gate bias voltage to the gate structure 108 may activate a channel of the fin. The cavities 120, 124 may have a dielectric parameter (e.g., k 1) that reduces parasitic capacitance between components of the device 100 during operation. For example, parasitic capacitance may be reduced as compared to a device that forms a spacer between a gate structure and an S/D contact using a silicon nitride material (e.g., where 6≦k≦7.5).

The example of FIG. 1 illustrates that the device 100 may be fabricated to include an air spacer and a contact without risking “punch-through” of the contact to the air spacer. For example, in FIG. 1, an etch process used to define a region in which the SAC 144 is formed is highly selective with respect to the seal material 130 (e.g., does not substantially etch the seal material 130). Thus, performance degradation (e.g., electrical shorts) associated with punch-through may be avoided while reducing parasitic capacitance using the cavities 120, 124. For example, the reduced parasitic capacitance may improve alternating current (AC) performance as compared to a device that utilizes a silicon nitride spacer. Additionally, capacitance reduction using the cavities 120, 124 may reduce transistor delay time and/or a switch energy associated with operation of the device 100.

FIGS. 2-19 illustrate certain example stages of a first fabrication process. The first fabrication process may be used to form a device, such as the device 100 of FIG. 1. The device may be included within a die, such as within a die of a wafer.

Referring to FIG. 2, a device during a first stage of the first fabrication process is depicted and generally designated 200. The device 200 may correspond to the device 100 during the first stage of the first fabrication process.

The device 200 may include the oxide region 104 of FIG. 1. The device 200 may further include a fin 202. The fin 202 may be formed using the substrate 102 of FIG. 1. For example, a shallow trench isolation (STI) process may be performed to etch out portions of the substrate 102 of FIG. 1 to define the fin 202. After defining the fin 202, an oxide material may be deposited on the etched portions to form the oxide region 104. In this case, the oxide region 104 may be formed on the substrate 102 of FIG. 1.

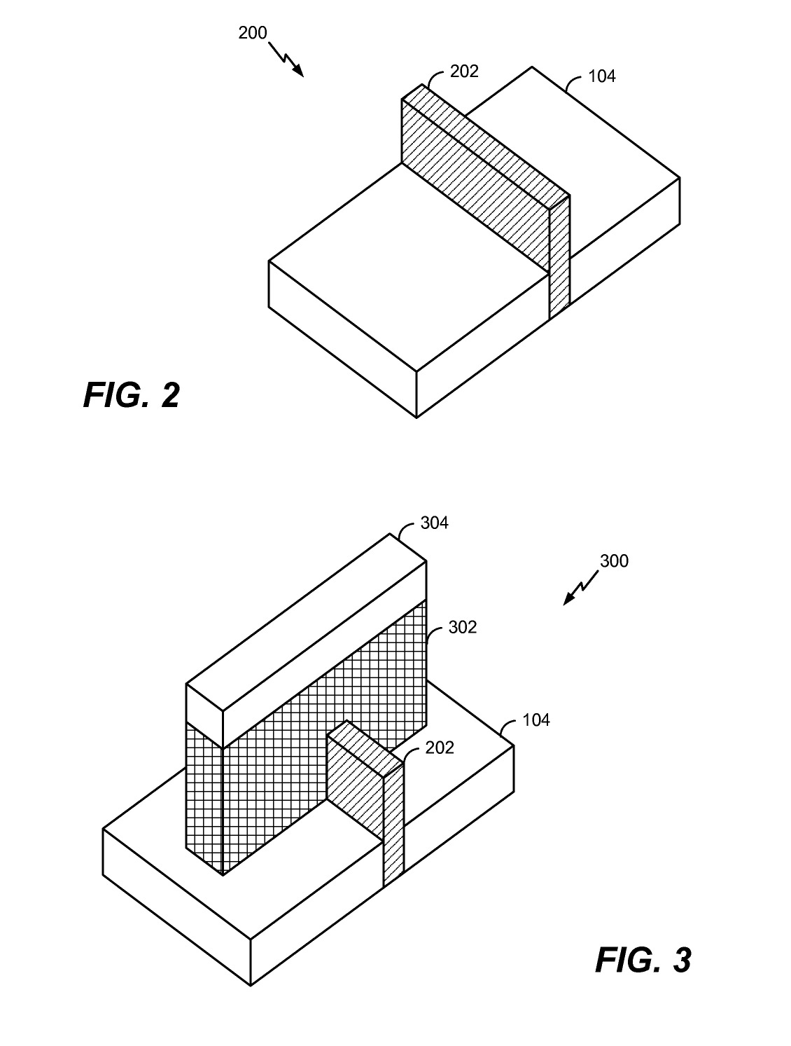

Referring to FIG. 3, a device during a second stage of the first fabrication process is depicted and generally designated 300. The second stage may follow the first stage described with reference to FIG. 2.

The device 300 may include a dummy gate 302. The dummy gate 302 may include a poly-silicon material. The dummy gate 302 may be formed (e.g., using a deposition process) on a portion of the fin 202, as illustrated in FIG. 3. A hard mask 304 may be formed (e.g., using a deposition process) on the dummy gate 302. The hard mask 304 may include an oxide material.

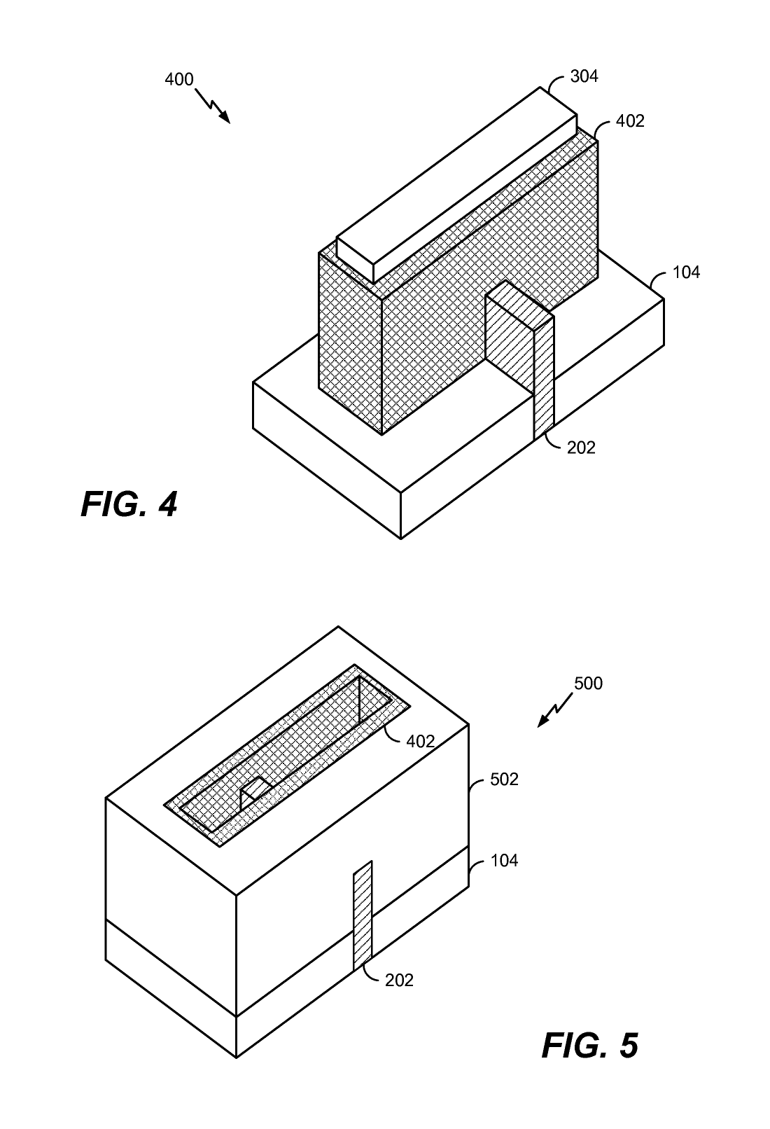

Referring to FIG. 4, a device during a third stage of the first fabrication process is depicted and generally designated 400. The third stage may follow the second stage described with reference to FIG. 3.

The device 400 may include a sacrificial spacer 402. The sacrificial spacer 402 may be formed around the dummy gate 302 of FIG. 3. For example, the sacrificial spacer 402 may be conformally formed (e.g., using a deposition process) on sidewalls of the dummy gate 302 of FIG. 3. The sacrificial spacer 402 may be in contact with portions of the oxide region 104, the fin 202, and the hard mask 304. The sacrificial spacer 402 may include a silicon nitride material or another material that includes nitride, as illustrative examples.

Depending on the particular application, one or more portions of the fin 202 may be removed, such as using an etch process. For example, a portion of the fin 202 may be removed prior to or after forming the sacrificial spacer 402. To illustrate, in at least one embodiment, a portion of the fin 202 is etched prior to forming the sacrificial spacer 402, and the sacrificial spacer 402 is formed “in place” of the removed portion of the fin 202. In this case, a gap may exist between the gate structure 108 and the fin 202 after formation of the gate structure 108. In another example, a portion of the fin 202 (e.g., adjacent to the sacrificial spacer 402) is removed after forming the sacrificial spacer 402. In this example, a dielectric (e.g., an oxide) may be formed in place of the removed portion of the fin (i.e., between the gate structure 108 and the fin 202 after formation of the gate structure 108). In other examples, the fin 202 is not etched. In this case, the gate structure 108 may be formed directly on the fin 202 (i.e., without an intervening gap or dielectric).

Referring to FIG. 5, a device during a fourth stage of the first fabrication process is depicted and generally designated 500. The fourth stage may follow the third stage described with reference to FIG. 4.

In FIG. 5, the dummy gate 302 and the hard mask 304 have been removed, such as using an etch process and a planarization process. For example, the dummy gate 302 may be removed using a wet etch or a dry etch, and the hard mask 304 may be removed using a chemical-mechanical planarization (CMP) process, as illustrative examples. After removal of the dummy gate 302 and the hard mask 304, the device 500 may include an opening defined by (e.g., interior to) the sacrificial spacer 402.

FIG. 5 further illustrates that the device 500 may include an oxide region 502. The oxide region 502 may be formed (e.g., grown or deposited) on sidewalls of the sacrificial spacer 402. The oxide region 502 may include a silicon oxide material, as an illustrative example. The oxide region 502 may correspond to a first interlayer dielectric (ILD0).

Referring to FIG. 6, a device during a fifth stage of the first fabrication process is depicted and generally designated 600. The fifth stage may follow the fourth stage described with reference to FIG. 5.

The device 600 includes a gate material 602 (e.g., a replacement gate). The gate material 602 can be formed (e.g., filled, deposited, etc.) within the opening defined by the sacrificial spacer 402. In a particular embodiment, the gate material 602 is formed using a metal gate process, such as in connection with a high-k metal gate (HKMG) fabrication process. The gate material 602 may include titanium, tantalum, silicon, aluminum, an alloy thereof, or a compound thereof (e.g., a nitride-based compound, such as titanium nitride, as an illustrative example). The gate material 602 may include the gate structure 108 of FIG. 1.

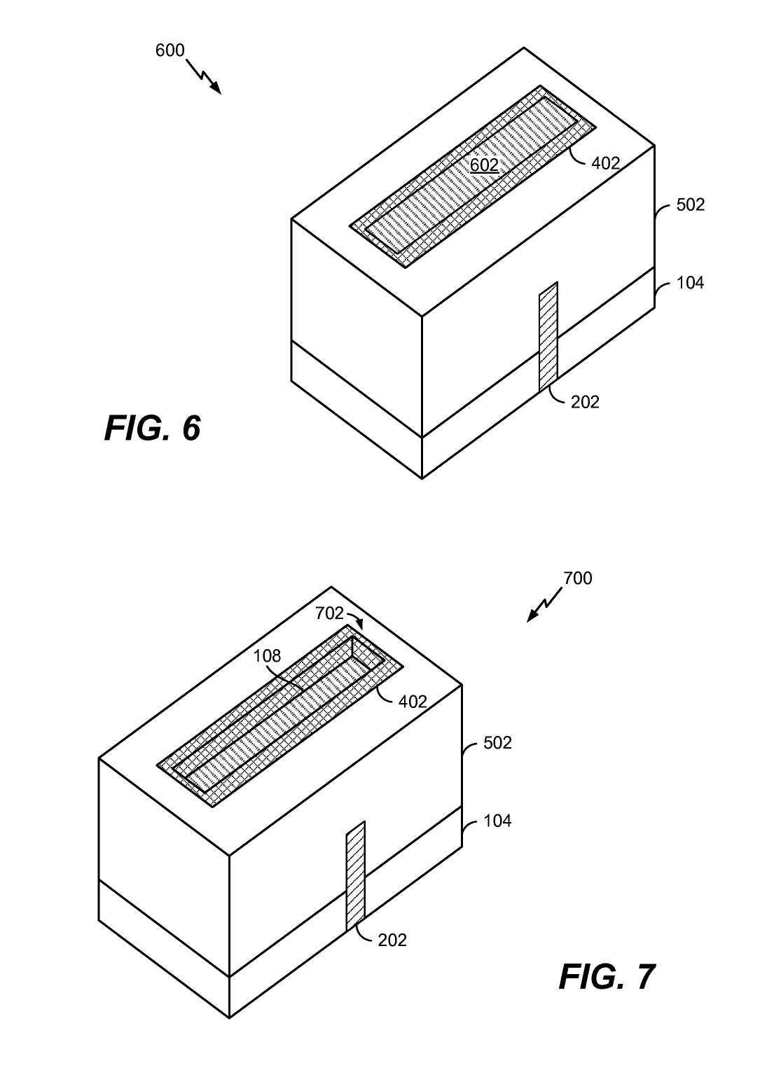

Referring to FIG. 7, a device during a sixth stage of the first fabrication process is depicted and generally designated 700. The sixth stage may follow the fifth stage described with reference to FIG. 6.

In FIG. 7, a recess etch has been performed on the gate material 602 of FIG. 6 to form the gate structure 108. The gate structure 108 may define an opening 702 with respect to the sacrificial spacer 402 (i.e., the gate structure 108 is recessed with respect to the sacrificial spacer 402).

Referring to FIG. 8, a device during a seventh stage of the first fabrication process is depicted and generally designated 800. The seventh stage may follow the sixth stage described with reference to FIG. 7.

The device 800 may include an etch stop material 802 (e.g., a C-doped nitride material). The etch stop material 802 may have an etch selectivity. For example, the etch stop material 802 may substantially resist certain etch processes but not other etch processes. The etch stop material 802 may be in contact with upper portions of the sacrificial spacer 402 and with upper portions of the gate structure 108. For example, the etch stop material 802 may be formed within the opening 702 defined by the gate structure 108. The etch stop material 802 may be formed using a deposition process.

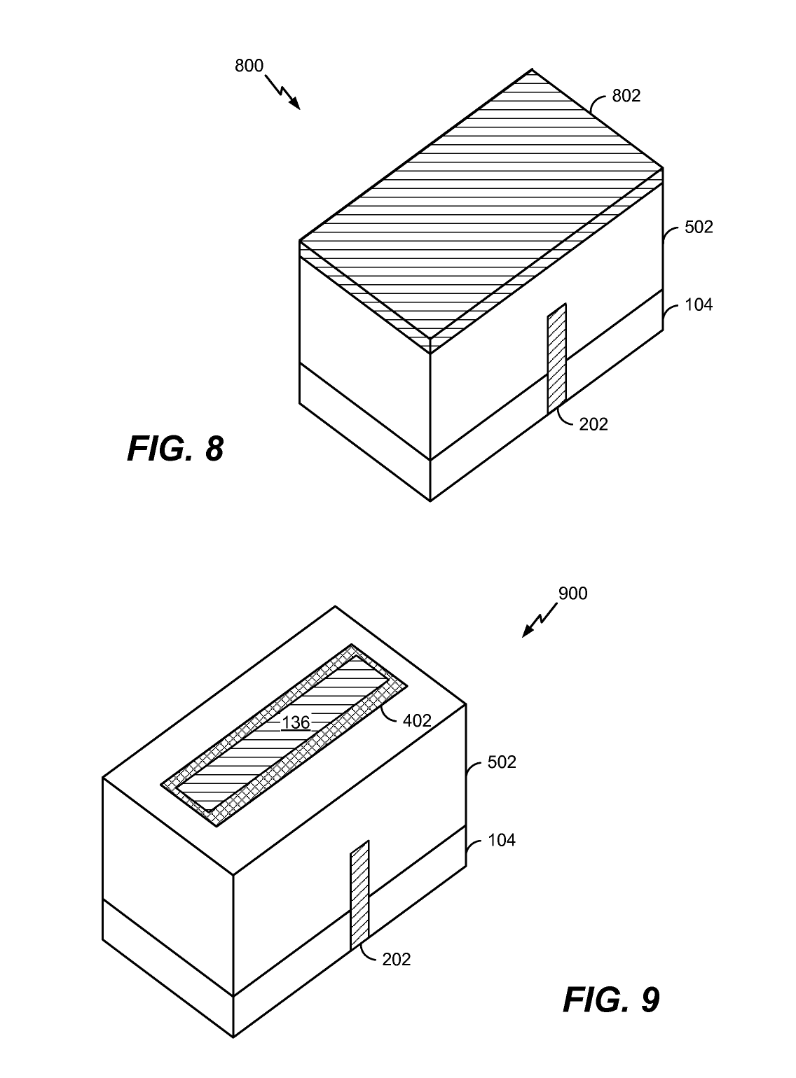

Referring to FIG. 9, a device during an eighth stage of the first fabrication process is depicted and generally designated 900. The eighth stage may follow the seventh stage described with reference to FIG. 8.

In FIG. 9, the etch stop material 802 of FIG. 8 has been planarized to form the etch stop material 136 of FIG. 1. The etch stop material 802 may be planarized using a CMP process to form the etch stop material 136, as an illustrative example. Planarizing the etch stop material 802 may expose the sacrificial spacer 402, as illustrated in FIG. 9.

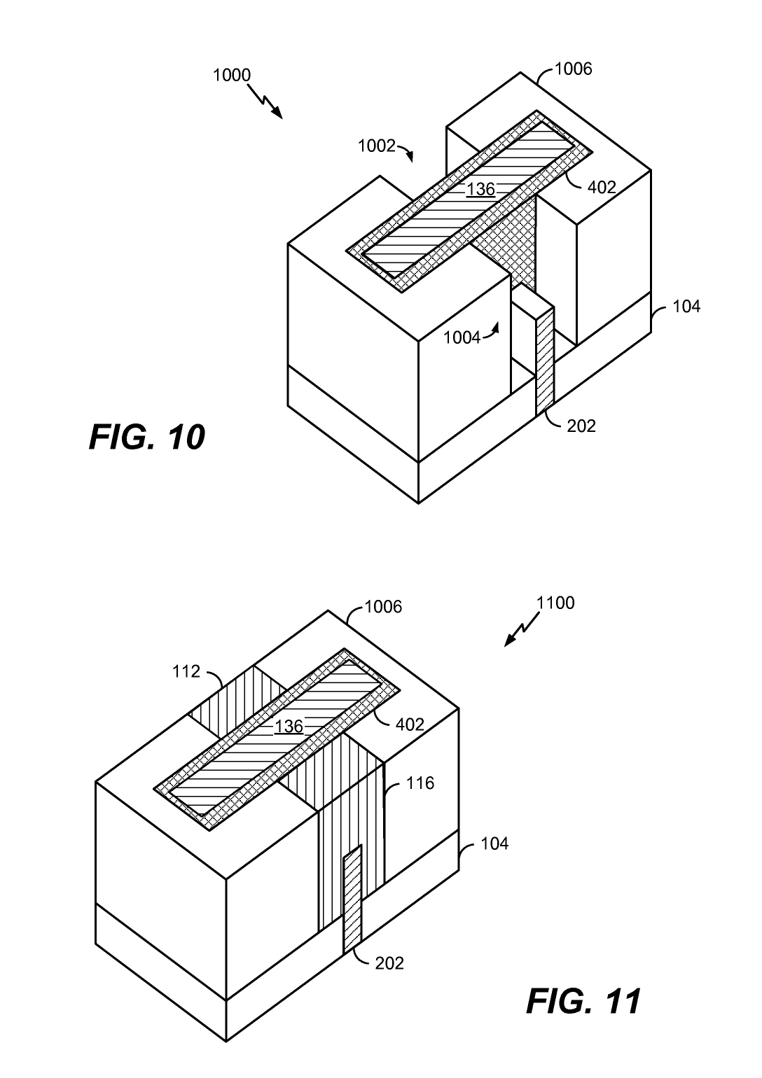

Referring to FIG. 10, a device during a ninth stage of the first fabrication process is depicted and generally designated 1000. The ninth stage may follow the eighth stage described with reference to FIG. 9.

In FIG. 10, the oxide region 502 of FIGS. 5-9 has been etched to define a region 1002 and a region 1004. For example, the regions 1002, 1004 may be formed by applying a selective etch process to the oxide region 502. The selective etch process may facilitate etching of oxide materials without etching the etch stop material 136, the fin 202, or the sacrificial spacer 402. Etching the oxide region 502 may define an oxide region 1006 (i.e., the remaining portion of the oxide region 502 after creating the regions 1002, 1004).

Referring to FIG. 11, a device during a tenth stage of the first fabrication process is depicted and generally designated 1100. The tenth stage may follow the ninth stage described with reference to FIG. 10.

In FIG. 11, the S/D contact 112 of FIG. 1 has been formed within the region 1002 of FIG. 10. FIG. 11 further depicts that the S/D contact 116 of FIG. 1 has been formed (e.g., deposited) within the region 1004 of FIG. 10. For example, the S/D contacts 112, 116 may be formed on surfaces of the oxide region 104 and on surfaces of the fin 202.

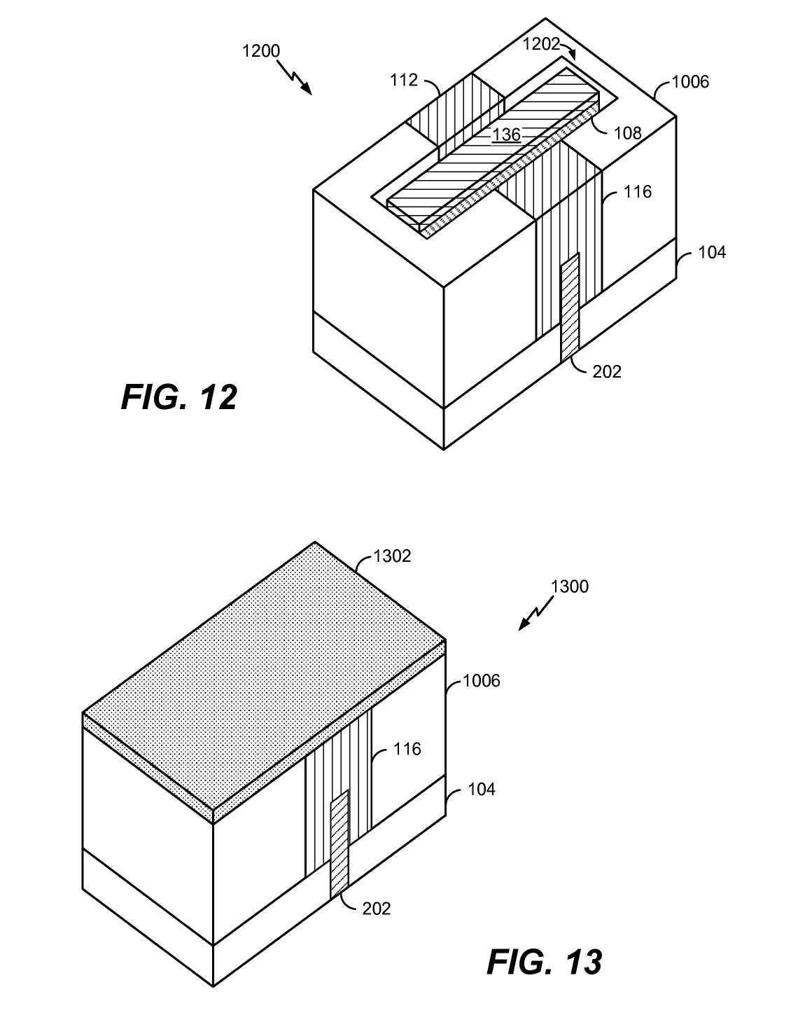

Referring to FIG. 12, a device during an eleventh stage of the first fabrication process is depicted and generally designated 1200. The eleventh stage may follow the tenth stage described with reference to FIG. 11.

In FIG. 12, the sacrificial spacer 402 has been removed to define a region 1202. For example, the sacrificial spacer 402 may be etched out using a wet etch or a dry etch, as non-limiting examples. The region 1202 may include the cavities 120, 124 of FIG. 1. Removing the sacrificial spacer 402 may expose sidewalls of the etch stop material 136 and the gate structure 108, as illustrated in FIG. 12.

Referring to FIG. 13, a device during an twelfth stage of the first fabrication process is depicted and generally designated 1300. The twelfth stage may follow the eleventh stage described with reference to FIG. 12.

The device 1300 may include a seal material 1302. The seal material 1302 may be formed (e.g., deposited) on upper surfaces of the etch stop material 136 and the oxide region 1006 and may also be formed on sidewalls of the S/D contacts 112, 116, the etch stop material 136, the gate structure 108, and the oxide region 1006 of FIG. 12. The seal material 1302 may be formed within a portion (but not all) of the region 1202 of FIG. 12. For example, the seal material 1302 may be formed using a non-conformal deposition process that causes the seal material 1302 to extend partially into the region 1202 in order to define the cavities 120, 124. In this example, the seal material 1302 may include the seal material 130 of FIG. 1, which may define the cavities 120, 124 of FIG. 1.

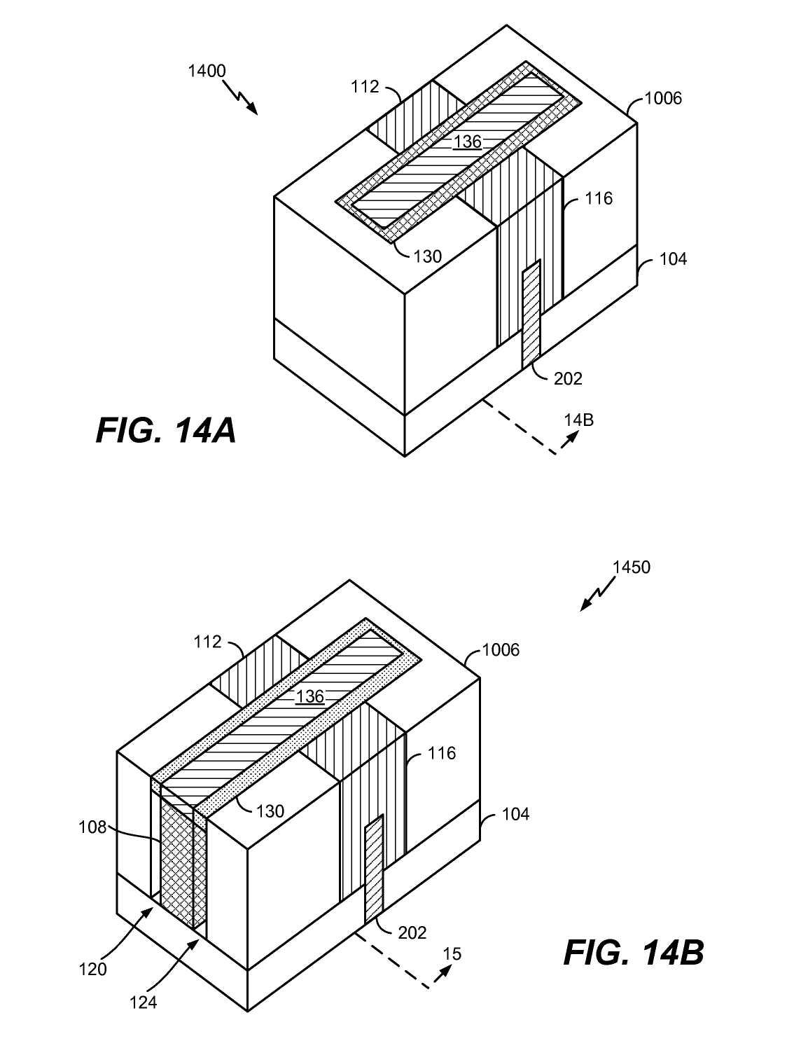

Referring to FIG. 14A, a device during a thirteenth stage of the first fabrication process is depicted and generally designated 1400. The thirteenth stage may follow the twelfth stage described with reference to FIG. 13.

FIG. 14A depicts that the seal material 1302 of FIG. 13 has been partially removed to define the seal material 130. For example, the seal material 1302 can be partially removed using a CMP process. Partially removing the seal material 1302 to define the seal material 130 may expose upper surfaces of the S/D contacts 112, 116, the etch stop material 136, and the oxide region 1006, as illustrated in FIG. 14A.

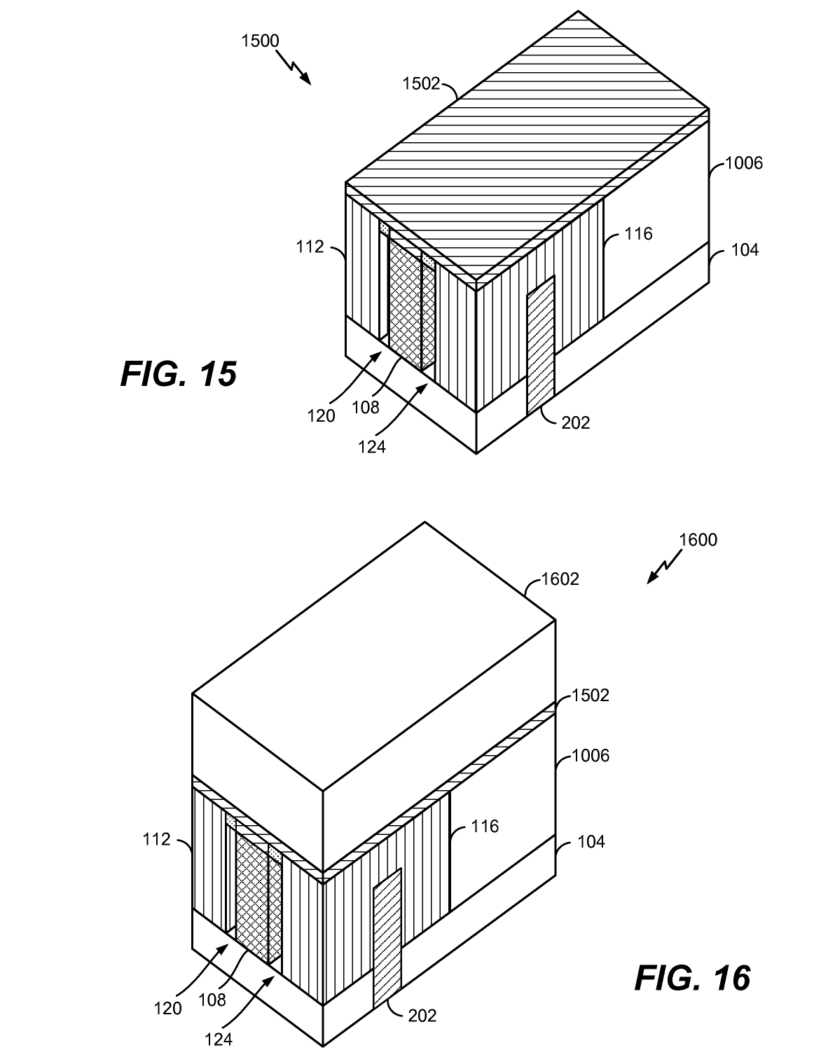

FIG. 14B illustrates a perspective view 1450 of the device 1400 taken along cutting line 14B. The perspective view 1450 illustrates that the device 1400 may include the gate structure 108, the cavities 120, 124, and the seal material 130. A cross-section of the perspective view 1450 taken along cutting line 15 may correspond to a portion of the cross-sectional view illustrated in FIG. 1 and also to the perspective view illustrated in FIG. 15.

Referring to FIG. 15, a device during a fourteenth stage of the first fabrication process is depicted and generally designated 1500. The fourteenth stage may follow the thirteenth stage described with reference to FIGS. 14A and 14B.

The device 1500 may include an etch stop material 1502 (e.g., a C-doped nitride material). The etch stop material 1502 may have an etch selectivity. For example, the etch stop material 1502 may substantially resist certain etch processes but not other etch processes. The etch stop material 1502 may be formed (e.g., deposited) on upper surfaces of the S/D contacts 112, 116, the seal material 130, the etch stop material 136, and the oxide region 1006. In an illustrative implementation, the etch stop materials 136, 1502 include a common material (e.g., C-doped nitride). In other implementations, the etch stop materials 136, 1502 may include one or more different materials.

Referring to FIG. 16, a device during a fifteenth stage of the first fabrication process is depicted and generally designated 1600. The fifteenth stage may follow the fourteenth stage described with reference to FIG. 15.

The device 1600 includes an oxide region 1602. The oxide region 1602 may be formed (e.g., grown or deposited) on an upper surface of the etch stop material 1502. The oxide region 1602 may include a silicon oxide material, as an illustrative example. The oxide region 1602 may correspond to a second interlayer dielectric (ILD1).

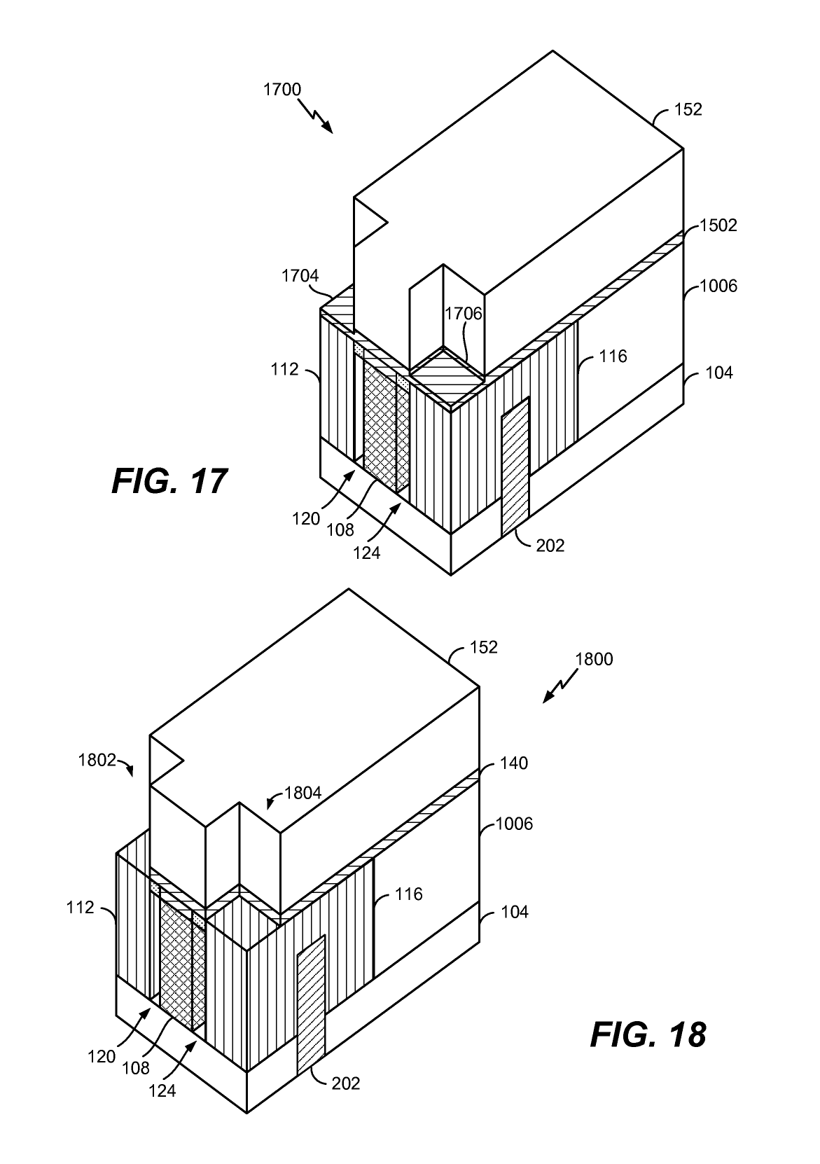

Referring to FIG. 17, a device during a sixteenth stage of the first fabrication process is depicted and generally designated 1700. The sixteenth stage may follow the fifteenth stage described with reference to FIG. 16.

In FIG. 17, portions of the oxide region 1602 of FIG. 16 have been removed to define the oxide region 152. For example, the portions of the oxide region 1602 may be etched out using a first etch process, such as a selective etch process. The first etch process may have a high etch rate with respect to oxide. For example, a ratio of an amount oxide of the oxide region 1602 etched by the first etch process to other materials subject to the first etch process (e.g., the etch stop material 1502) may satisfy a threshold ratio. The etch stop material 1502 may resist the selective etch process. The selective etch process may expose portions 1704, 1706 of the etch stop material 1502.

Referring to FIG. 18, a device during a seventeenth stage of the first fabrication process is depicted and generally designated 1800. The seventeenth stage may follow the sixteenth stage described with reference to FIG. 17.

In FIG. 18, the portions 1704, 1706 of the etch stop material 1502 have been removed (e.g., etched using a selective etch process) to define the etch stop material 140. For example, the portions 1704, 1706 may be etched using a second etch process that is different than the first etch process used to etch the oxide region 1602. In a particular embodiment, the etch stop material 1502 includes C-doped nitride, and the second etch process has a high etch rate with respect to the C-doped nitride and a low etch rate with respect to oxide i.e., high etch selectivity to oxide. For example, a ratio of an amount of C-doped nitride of the etch stop material 1502 etched by the second etch process to other materials subject to the second etch process (e.g., oxide of the oxide region 152 and/or materials of the S/D contacts 112, 116) may satisfy a threshold ratio. Removing the portions 1704, 1706 further defines etched regions 1802, 1804. Removing the portions 1704, 1706 may expose upper surface portions of the S/D contacts 112, 116.

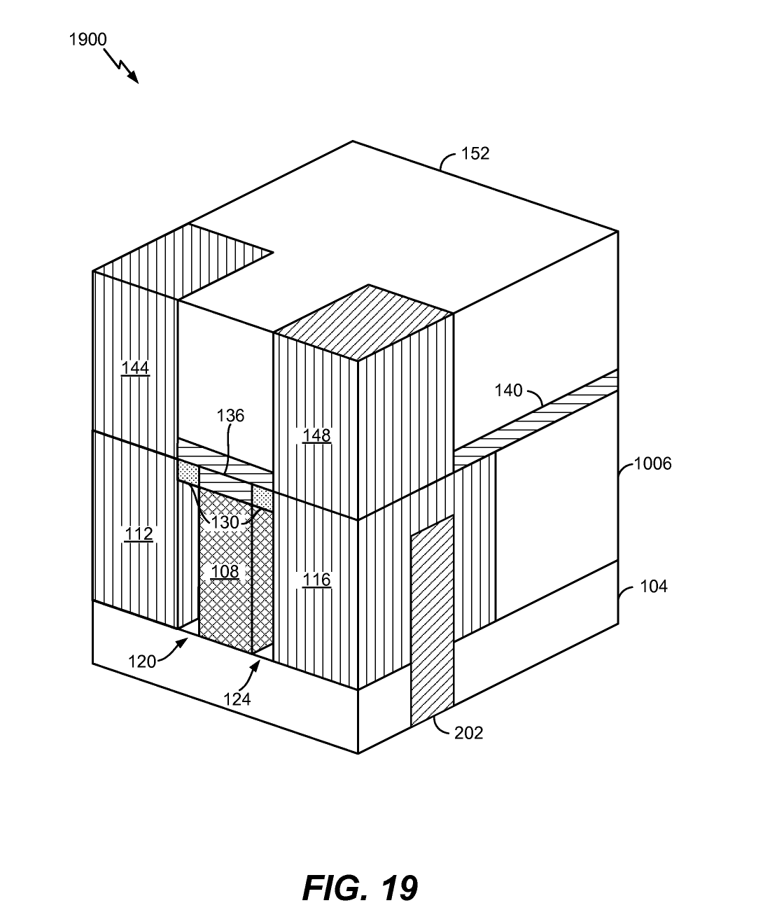

Referring to FIG. 19, a device during an eighteenth stage of the first fabrication process is depicted and generally designated 1900. The eighteenth stage may follow the seventeenth stage described with reference to FIG. 18. The device 1900 may correspond to the device 100 of FIG. 1.

In FIG. 19, the etched regions 1802, 1804 of FIG. 18 have been filled to form the SACs 144, 148. For example, a metal material (e.g., tungsten) may be deposited on exposed surfaces of the S/D contacts 112, 116 using a deposition process to form the SACs 144, 148. The S/D contacts 112, 116 and the SACs 144, 148 may form “two-level” contacts that extend between multiple device layers (e.g., between ILD0 and ILD1).

The examples of FIGS. 2-19 illustrate a fabrication process to create one or more air spacers (e.g., the cavities 120, 124) to reduce parasitic capacitance associated with operation of a device. To reduce likelihood of a contact “punching through” to the air spacer, the device may include a SAC (e.g., one or both of the SACs 144, 148). For example, by using a selective etch process to create the etched regions 1802, 1804, upper surfaces of the S/D contacts 112, 116, the seal material 130, and/or the oxide region 152 may function as etch stop layers. In this case, misalignment of the SACs 144, 148 is unlikely to result in punch-through. Thus, yield and performance are improved, such as by reducing the likelihood of an electrical short caused by punch-through.

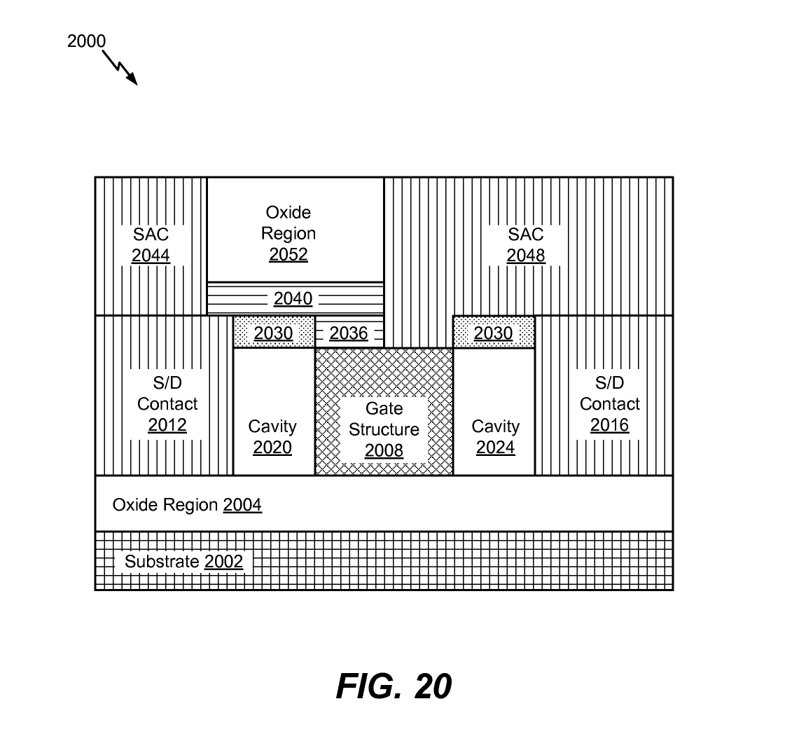

The SACs 144, 148 illustrated in FIGS. 1 and 19 may correspond to source and drain contacts of a transistor device, such as a FinFET device. Alternatively or in addition, a device may include a butted contact, such as a butted contact that forms a gate-to-source short or a gate-to-drain short. For example, a diode device may include a gate-to-drain short, and the diode device may be included in a current mirror device, as illustrative examples. As another example, a capacitor device may include a gate-to-drain short and a gate-to-source short. An illustrative example of a butted contact is described further with reference to FIG. 20.

Referring to FIG. 20, a particular illustrative embodiment of a device is depicted and generally designated 2000. The device 2000 may be a FET device, such as a FinFET device. An example of a FinFET device is a 3D FinFET device.

The device 2000 includes a substrate 2002. The substrate 2002 may be a semiconductor substrate or a glass substrate, as illustrative examples. An oxide region 2004 may be formed on the substrate 2002. For example, the device 2000 may have an SOI configuration in which one or more devices (e.g., a transistor) are formed on an oxide region, such as the oxide region 2004. The oxide region 2004 may include a silicon oxide material, as an illustrative example. In other implementations, the device 2000 may have another configuration. For example, the device 2000 may be fabricated using a CMOS process that forms components directly on the substrate 2002 (instead of an on oxide region). In this example, the oxide region 2004 may be omitted from the device 2000.

The device 2000 may further include a gate structure 2008. The gate structure 2008 may include one or more conductive materials, such as one or more metal materials. In an illustrative implementation, the gate structure 2008 is a metal gate. In this case, the device 2000 may be a high-k metal gate (HKMG) device, where k indicates a dielectric parameter.

The device 2000 may further include an S/D contact 2012 and an S/D contact 2016. In the example of FIG. 20, the gate structure 2008 and the S/D contact 2012 may define a cavity 2020, and the gate structure 2008 and the S/D contact 2016 may define a cavity 2024. The cavities 2020, 2024 may correspond to air-filled spacers or vacuum spacers.

The device 2000 may further include a seal material 2030. The seal material 2030 may be configured to seal (or substantially seal) the cavities 2020, 2024. For example, the seal material 2030 may be configured to seal air (or another gas) within the cavities 2020, 2024. In other cases, the cavities 2020, 2024 may correspond to vacuum spacers, and the seal material 2030 may be configured to prevent or inhibit air from reaching the cavities 2020, 2024. The seal material 2030 may include a silicon oxide material or a carbon-doped silicon oxide material, as illustrative examples. The seal material 2030 may have an etch selectivity that resists some (but not all) etch processes used during fabrication of the device 2000. For example, the seal material 2030 may be etch selective with respect to nitride and/or oxide (so an etch process etches nitride and/or oxide more rapidly than the seal material 2030). The seal material 2030 may be formed using a deposition process, such as using a chemical vapor deposition (CVD) process.

The device 2000 may further include an etch stop material 2036 and an etch stop material 2040. The etch stop materials 2036, 2040 may have an etch selectivity that resists some (but not all) etch processes used during fabrication of the device 2000. The etch stop materials 2036, 2040 may include a C-doped nitride material, as an illustrative example. An oxide region 2052 may be formed on the etch stop material 2040.

The device 2000 may further include an SAC 2044 and an SAC 2048. The SAC 2044 is formed on the S/D contact 2012, and the SAC 2048 is formed on the S/D contact 2016 and also on portions of the seal material 2030 and the gate structure 2008. In the example of FIG. 20, the SAC 2048 is a butted contact that forms a short between the gate structure 2008 and the S/D contact 2016. The SACs 2044, 2048 may include one or more conductive materials, such as one or more metal materials (e.g., tungsten). The SAC 2044 and the S/D contact 2012 may form a two-level metal contact structure, and the SAC 2048 and the S/D contact 2016 may form another two-level metal contact structure. A two-level contact structure may include a single material or multiple materials.

The SACs 2044, 2048 may be formed within etched regions of the device 2000 that are etched using a selective etch process. For example, as described further below, an etch process may create the etched regions by selectively etching one or more materials of the device 2000 without substantially etching the gate structure 2008, the seal material 2030, and/or the S/D contacts 2012, 2016. As a result, the etched regions (and the SACs 2044, 2048) can be “misaligned” without inadvertently punching through materials of the device 2000.

To further illustrate, the example of FIG. 20 depicts that the SAC 2048 adjoins a portion of the seal material 2030. In a conventional device, an etch process used to create an etched region in which the SAC 2048 is formed can inadvertently “punch through” the seal material 2030, exposing the cavity 2024. In this case, exposing the cavity 2024 may cause the cavity 2024 to be filled with material during formation of the SAC 2048, which may alter or degrade operation of the device 2000 (e.g., by changing capacitance of the device 2000). By using a selective etch process to create the etched region, punch-through can be avoided.

After fabrication, the device 2000 may be integrated within an electronic device, such as within a mobile device, as an illustrative example. During operation of the electronic device, the device 2000 may be biased using bias voltages. For example, a bias voltage (or a ground voltage) may be applied at the SAC 2044 to bias a source or drain region of the device 2000 (not shown in FIG. 20) via the S/D contact 2012. As another example, a bias voltage (or a ground voltage) may be applied at the SAC 2048 to bias the gate structure 2008 and a source or drain region of the device 2000 (not shown in FIG. 20) via the S/D contact 2016. Applying a bias voltage to the SAC 2048 may activate a channel between the S/D contacts 2012, 2016. For example, in a 3D FinFET implementation, a fin (not shown in FIG. 20) may adjoin the S/D contacts 2012, 2016. In this case, application of a gate bias voltage to the SAC 2048 may activate a channel of the fin. The cavities 2020, 2024 may have a dielectric parameter (e.g., k 1) that reduces parasitic capacitance between components of the device 2000 during operation. For example, parasitic capacitance may be reduced as compared to a device that forms a spacer between a gate structure and an S/D contact using a silicon nitride material (e.g., where 6≦k≦7.5).

The example of FIG. 20 illustrates that the device 2000 may be fabricated to include an air spacer and a contact without risking “punch-through” of the contact to the air spacer. For example, in FIG. 20, an etch process used to define a region in which the SAC 2048 is formed is highly selective with respect to the seal material 2030 (e.g., does not substantially etch the seal material 2030). Thus, performance degradation associated with punch-through may be avoided while reducing parasitic capacitance using the cavities 2020, 2024. For example, the reduced parasitic capacitance may improve alternating current (AC) performance as compared to a device that utilizes a silicon nitride spacer. Additionally, capacitance reduction using the cavities 2020, 2024 may reduce transistor delay time and/or a switch energy associated with operation of the device 2000.

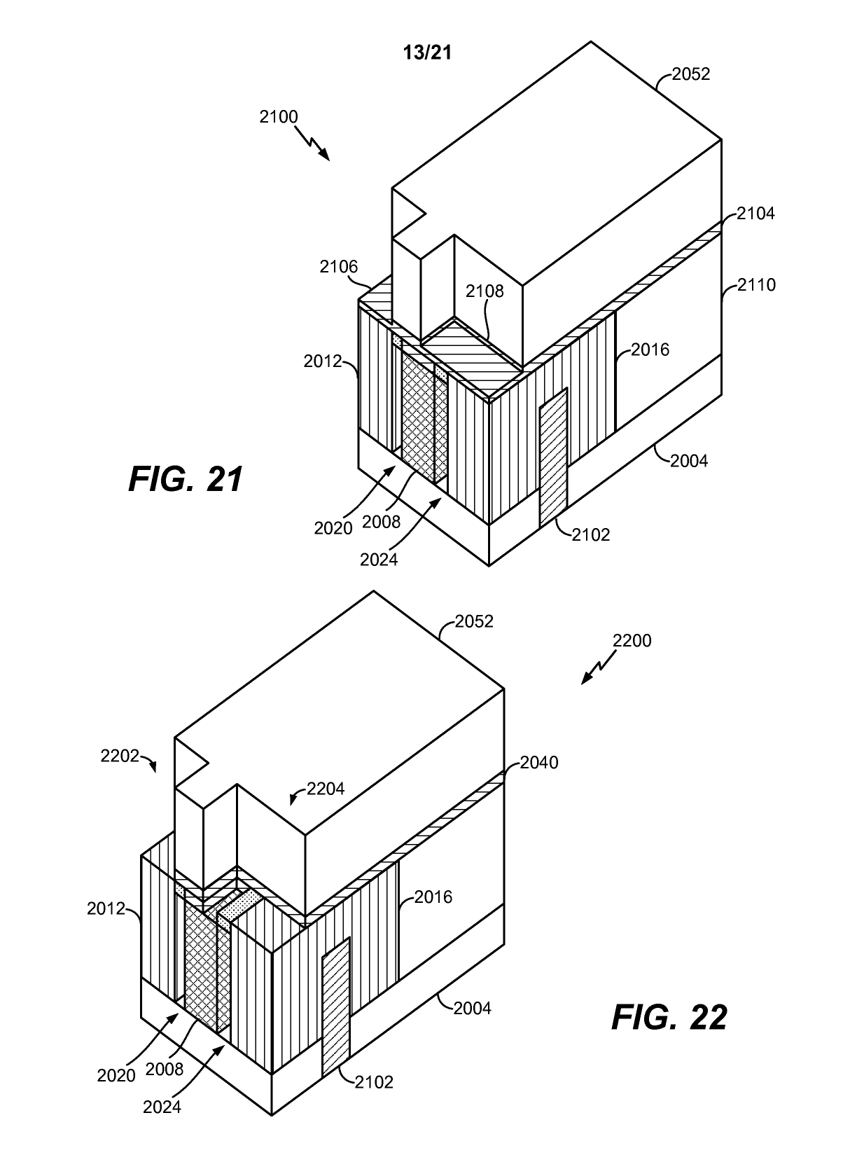

FIGS. 21-23 illustrate certain example stages of a second fabrication process. The second fabrication process may be used to form a device, such as the device 2000 of FIG. 20. The device may be included within a die, such as within a die of a wafer.

Referring to FIG. 21, a device during a first stage of the second fabrication process is depicted and generally designated 2100. The device 2100 may correspond to the device 2000 of FIG. 20. The first stage of the second fabrication process may follow one or more stages of the first fabrication process described with reference to FIGS. 2-19. For example, the first stage of the second fabrication process of FIG. 21 may follow the fifteenth stage of the first fabrication process described with reference to FIG. 16.

To further illustrate, the etch process described with reference to the fin 202 of FIG. 2 may be used to define a fin 2102 of the device 2100. As another example, the deposition process described with reference to the etch stop material 1502 of FIG. 15 may be used to form an etch stop material 2104 of the device 2100. As another example, an oxide region 2110 of the device 2100 may be formed as described with reference to the oxide region 1006 of FIG. 10. Further, the oxide region 2004, the gate structure 2008, the S/D contacts 2012, 2016, the cavities 2020, 2024, and the oxide region 2052 can be formed or defined using certain techniques described with reference to the first fabrication process of FIGS. 2-19.

The etch stop material 2104 of FIG. 21 may include a C-doped nitride material. The etch stop material 2104 may have an etch selectivity. For example, the etch stop material 2104 may substantially resist certain etch processes (e.g., the first etch process described with reference to FIG. 17) but not other etch processes (e.g., the second etch process described with reference to FIG. 18). The etch stop material 2104 may include portions 2106, 2108. In the example of FIG. 21, the portions 2106, 2108 are of different areas. For example, in the example of FIG. 21, the portion 2108 has a greater area than the portion 2106, such as to facilitate formation of a butted contact to form a short between the gate structure 2008 and the S/D contact 2016.

Referring to FIG. 22, a device during a second stage of the second fabrication process is depicted and generally designated 2200. The second stage of FIG. 22 may follow the first stage described with reference to FIG. 21.

In FIG. 22, the portions 2106, 2108 of the etch stop material 2104 of FIG. 21 have been removed (e.g., etched, such as using the second etch process described with reference to FIG. 18) to define the etch stop material 2040. Removing the portions 2106, 2108 further defines etched regions 2202, 2204. Removing the portions 1704, 1706 may expose upper surface portions of the gate structure 2008, the S/D contacts 2012, 2016, and the seal material 2030 of FIG. 20.

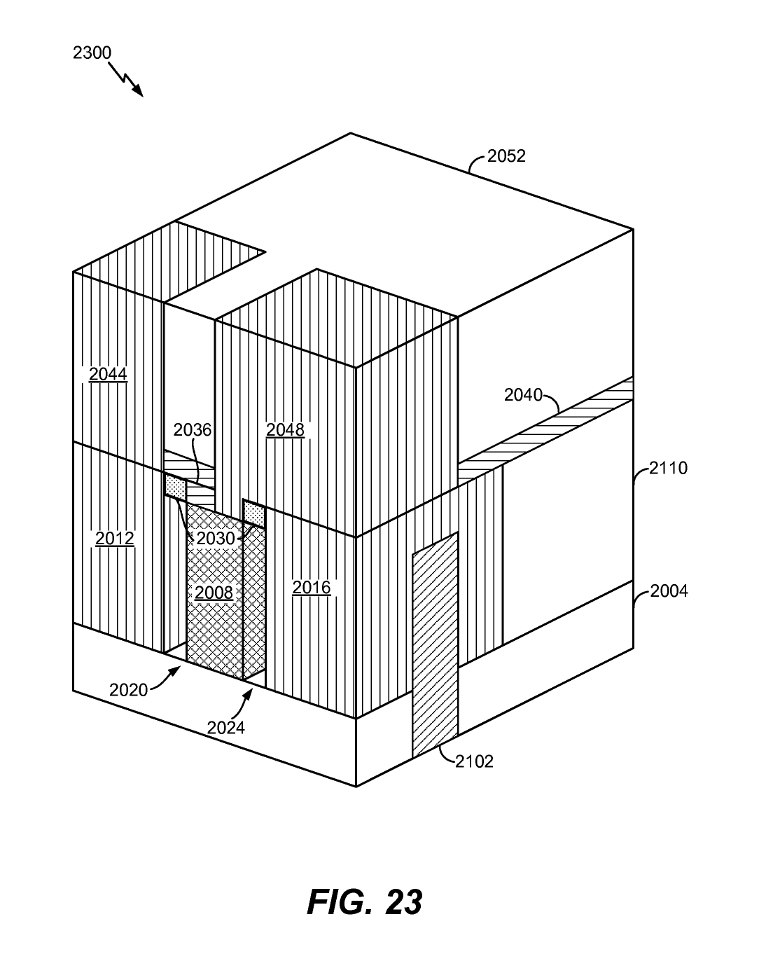

Referring to FIG. 23, a device during a third stage of the second fabrication process is depicted and generally designated 2300. The third stage of FIG. 23 may follow the second stage of FIG. 22. The device 2300 may correspond to the device 2000 of FIG. 20.

In FIG. 23, the etched regions 2202, 2204 of FIG. 22 have been filled to form the SACs 2044, 2048. For example, a metal material (e.g., tungsten) may be deposited on upper surface portions of the gate structure 2008, the S/D contacts 2012, 2016, and the seal material 2030 using a deposition process to form the SACs 2044, 2048. The S/D contacts 2012, 2016 and the SACs 2044, 2048 may form “two-level” contacts that extend between multiple device layers (e.g., between ILD0 and ILD1).

The examples of FIGS. 21-23 illustrate a fabrication process to create one or more air spacers (e.g., the cavities 2020, 2024) to reduce parasitic capacitance associated with operation of a device. To reduce likelihood of a contact “punching through” to the air spacer, the device may include a SAC (e.g., one or both of the SACs 2044, 2048). For example, by using a selective etch process to create the etched regions 2202, 2204, upper surfaces of the gate structure 2008, the S/D contacts 2012, 2016, and/or the seal material 2030 may function as etch stop layers. In this case, misalignment of the SACs 2044, 2048 is unlikely to result in punch-through. Thus, yield and performance are improved, such as by reducing the likelihood of an electrical short caused by punch-through.

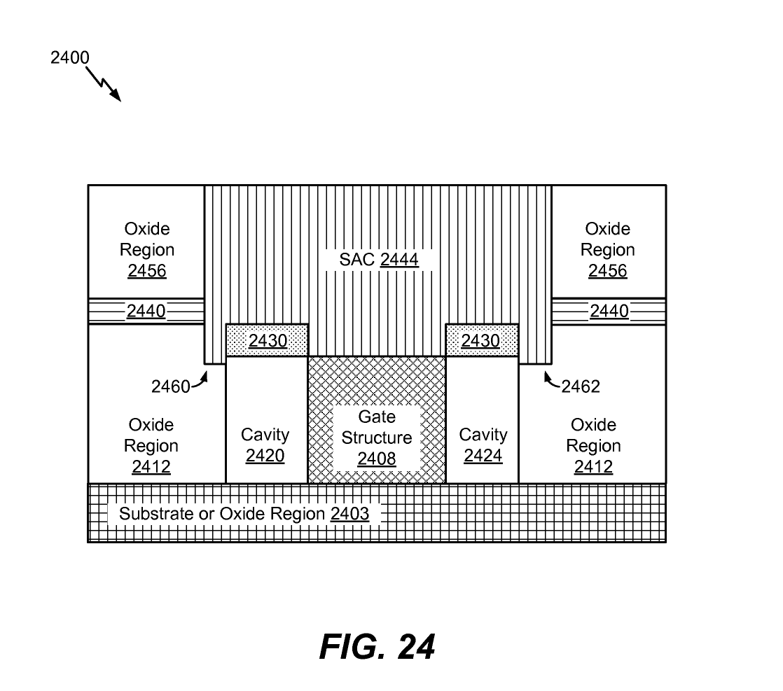

Alternatively or in addition to the examples described with reference to FIGS. 1-23, a device may include a gate contact. For example, a gate contact may be configured to bias a gate structure of a transistor, such as to activate (or deactivate) a channel of the transistor. An example of a gate contact is described further with reference to FIG. 24.

Referring to FIG. 24, a particular illustrative embodiment of a device is depicted and generally designated 2400. The device 2400 may be a FET device, such as a FinFET device. An example of a FinFET device is a 3D FinFET device.

The device 2400 includes a substrate or oxide region 2403. The substrate or oxide region 2403 may be a semiconductor substrate, a glass substrate, or an oxide region formed on a substrate, as illustrative examples.

The device 2400 may further include a gate structure 2408. The gate structure 2408 may include one or more conductive materials, such as one or more metal materials. In an illustrative implementation, the gate structure 2408 is a metal gate. In this case, the device 2400 may be a high-k metal gate (HKMG) device, where k indicates a dielectric parameter. In an illustrative implementation, the device 2400 is a FinFET device that includes a fin formed using the substrate or oxide region 2403. In this case, the gate structure 2408 may adjoin an oxide portion of the gate or oxide region 2403. The device 2400 may be fabricated using a CMOS process that forms components directly on the substrate or oxide region 2403 (instead of an on oxide region). In this example, the gate structure 2408 may adjoin source and drain regions (e.g., highly doped silicon areas) formed within the substrate or oxide region 2403.

The device 2400 may further include an oxide region 2412. The oxide region 2412 may correspond to a first interlayer dielectric (ILD0) of the device 2400. In the example of FIG. 24, the gate structure 2408 and the oxide region 2412 may define a cavity 2420, and the gate structure 2408 and the oxide region 2412 may define a cavity 2424. The cavities 2420, 2424 may correspond to air-filled spacers or vacuum spacers.

The device 2400 may further include a seal material 2430. The seal material 2430 may be configured to seal (or substantially seal) the cavities 2420, 2424. For example, the seal material 2430 may be configured to seal air (or another gas) within the cavities 2420, 2424. In other cases, the cavities 2420, 2424 may correspond to vacuum spacers, and the seal material 2430 may be configured to prevent or inhibit air from reaching the cavities 2420, 2424. The seal material 2430 may include a silicon oxide material or a carbon-doped silicon oxide material, as illustrative examples. The seal material 2430 may have an etch selectivity that resists some (but not all) etch processes used during fabrication of the device 2400. For example, the seal material 2430 may be etch selective with respect to nitride and/or oxide (so an etch process etches nitride and/or oxide more rapidly than the seal material 2430). The seal material 2430 may be formed using a deposition process, such as using a chemical vapor deposition (CVD) process.

The device 2400 may further include an etch stop material 2440. The etch stop material 2440 may have an etch selectivity that resists some (but not all) etch processes used during fabrication of the device 2400. The etch stop material 2440 may include a C-doped nitride material, as an illustrative example. An oxide region 2456 may be formed on the etch stop material 2440. The oxide region 2456 may correspond to a second interlayer dielectric (ILD1) of the device 2400.

The device 2400 may further include a SAC 2444. The SAC 2444 is formed on upper surfaces of the gate structure 2408, the seal material 2430, and the oxide region 2412. In the example of FIG. 24, the SAC 2444 is a gate contact that adjoins the gate structure 2408. The SAC 2444 may include one or more conductive materials, such as one or more metal materials (e.g., tungsten).

The SAC 2444 may be formed within etched regions of the device 2400 that are etched using a selective etch process. For example, as described further below, an etch process may create the etched regions by selectively etching one or more materials of the device 2400 without substantially etching the gate structure 2408 and/or the seal material 2430. As a result, the etched regions (and the SAC 2444) can be “misaligned” without inadvertently punching through materials of the device 2400.

To further illustrate, the example of FIG. 24 depicts that the SAC 2444 is formed within recesses 2460, 2462 of the oxide region 2412. The recesses 2460, 2462 may be caused by misalignment and/or over-etching during formation of an etched region in which the SAC 2444 is formed (i.e., by etching too “wide” or too “deep”). In a conventional device, an etch process used to create an etched region in which the SAC 2444 is formed can inadvertently “punch through” the seal material 2430, exposing one or both of the cavities 2420, 2424. In this case, one or both of the cavities 2420, 2424 may be filled with material during formation of the SAC 2444, which may alter or degrade operation of the device 2400 (e.g., by changing capacitance of the device 2400). By using a selective etch process to create the etched region, punch-through can be avoided.

After fabrication, the device 2400 may be integrated within an electronic device, such as within a mobile device, as an illustrative example. During operation of the electronic device, the device 2400 may be biased using bias voltages. For example, a bias voltage (or a ground voltage) may be applied at the SAC 2444 to bias the gate structure 2408. Biasing the gate structure 2408 may activate a channel between source and drain regions of the device 2400 (not shown in FIG. 24). For example, in a 3D FinFET implementation, a fin (not shown in FIG. 24) may include the source and drain regions. In this case, application of a gate bias voltage to the SAC 2444 may activate a channel of the fin. The cavities 2420, 2424 may have a dielectric parameter (e.g., k 1) that reduces parasitic capacitance between components of the device 2400 during operation. For example, parasitic capacitance may be reduced as compared to a device that forms a spacer between a gate structure and an S/D contact using a silicon nitride material (e.g., where 6≦k≦7.5).

The example of FIG. 24 illustrates that the device 2400 may be fabricated to include an air spacer and a contact without risking “punch-through” of the contact to the air spacer. For example, in FIG. 24, an etch process used to define a region in which the SAC 2444 is formed is highly selective with respect to the seal material 2430 (e.g., does not substantially etch the seal material 2430). Thus, performance degradation associated with punch-through may be avoided while reducing parasitic capacitance using the cavities 2420, 2424. For example, the reduced parasitic capacitance may improve alternating current (AC) performance as compared to a device that utilizes a silicon nitride spacer. Additionally, capacitance reduction using the cavities 2420, 2424 may reduce transistor delay time and/or a switch energy associated with operation of the device 2400.

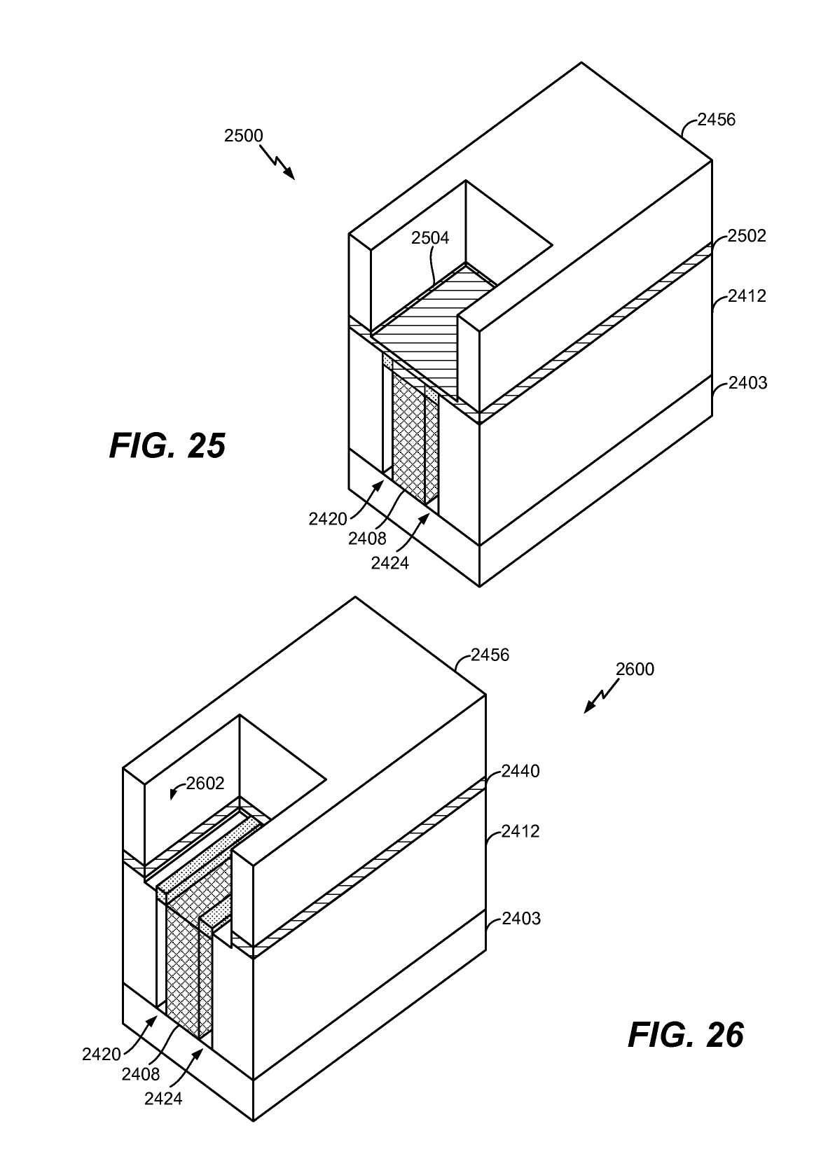

FIGS. 25-27 illustrate certain example stages of a third fabrication process. The third fabrication process may be used to form a device, such as the device 2400 of FIG. 24. The device may be included within a die, such as within a die of a wafer.

Referring to FIG. 25, a device during a first stage of the third fabrication process is depicted and generally designated 2500. The device 2500 may correspond to the device 2400 of FIG. 24. The first stage of the third fabrication process may follow one or more stages of the first fabrication process described with reference to FIGS. 2-19 and/or one or more stages of the second fabrication process described with reference to FIGS. 21-23. For example, the first stage of the second fabrication process of FIG. 21 may follow the fifteenth stage of the first fabrication process described with reference to FIG. 16.

To further illustrate, the deposition process described with reference to the etch stop material 1502 of FIG. 15 may be used to form an etch stop material 2502 of the device 2500. Further, the substrate or oxide region 2403, the gate structure 2408, the oxide region 2412, the cavities 2420, 2424, and the oxide region 2456 can be formed or defined using certain techniques described with reference to the first fabrication process of FIGS. 2-19 and/or the second fabrication process of FIGS. 21-23.

The etch stop material 2502 of FIG. 25 may include a C-doped nitride material. The etch stop material 2502 may have an etch selectivity. For example, the etch stop material 2502 may substantially resist certain etch processes (e.g., the first etch process described with reference to FIG. 17) but not other etch processes (e.g., the second etch process described with reference to FIG. 18). The etch stop material 2502 may include a portion 2504.

Referring to FIG. 26, a device during a second stage of the third fabrication process is depicted and generally designated 2600. The second stage of FIG. 26 may follow the first stage described with reference to FIG. 25.

In FIG. 26, the portion 2504 of FIG. 25 has been removed (e.g., etched using the second etch process described with reference to FIG. 18) to define the etch stop material 2440. Removing the portion 2504 further defines an etched region 2602. Removing the portion 2504 may expose upper surface portions of the gate structure 2408, the oxide region 2412, and the seal material 2430 of FIG. 24.

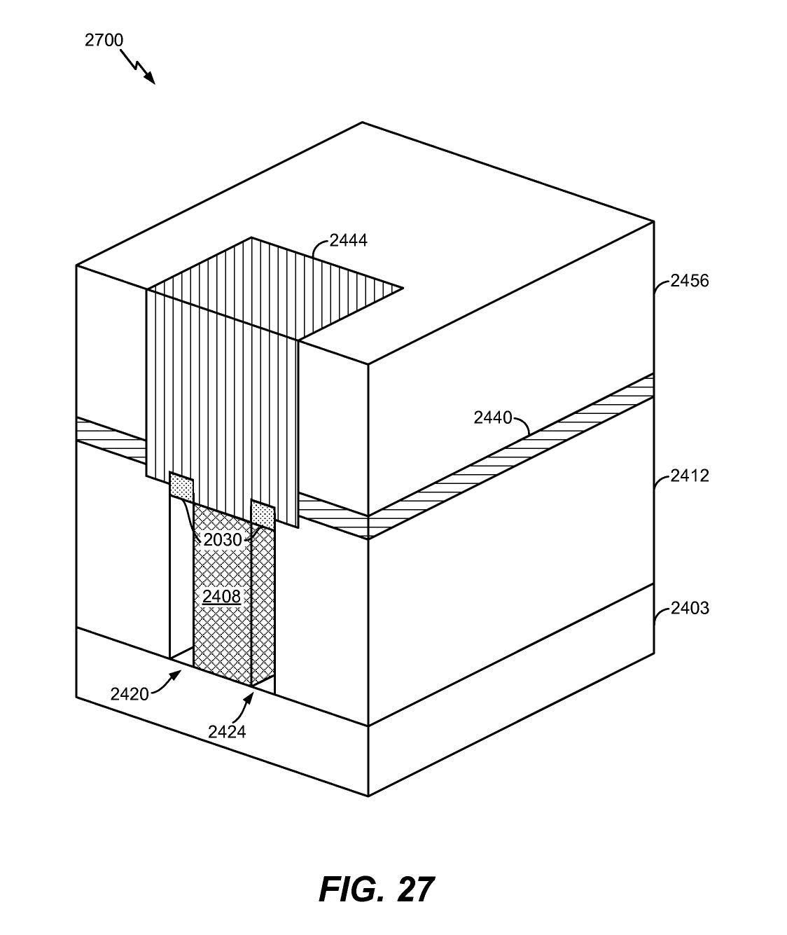

Referring to FIG. 27, a device during a third stage of the third fabrication process is depicted and generally designated 2700. The third stage of FIG. 27 may follow the second stage of FIG. 26. The device 2700 may correspond to the device 2400 of FIG. 24.

In FIG. 27, the etched region 2602 of FIG. 26 has been filled to form the SAC 2444. For example, a metal material (e.g., tungsten) may be deposited on upper surface portions of the gate structure 2408, the oxide region 2412, and the seal material 2430 using a deposition process to form the SAC 2444. The SAC 2444 may correspond to a gate contact that is configured to apply a bias voltage (or a ground voltage) to the gate structure 2408, such as to activate (or deactivate) a channel of the device 2700.

The examples of FIGS. 25-27 illustrate a fabrication process to create one or more air spacers (e.g., the cavities 2420, 2424) to reduce parasitic capacitance associated with operation of a device. To reduce likelihood of a contact “punching through” to the air spacer, the device may include a SAC, such as the SAC 2444. For example, by using a selective etch process to create the etched region 2602 of FIG. 26, upper surfaces of the gate structure 2408, the oxide region 2412, and the seal material 2430 may function as etch stop layers. In this case, misalignment of the SAC 2444 is unlikely to result in punch-through. Thus, yield and performance are improved, such as by reducing the likelihood of an electrical short caused by punch-through.

Accordingly, the examples of FIGS. 1-27 describe various illustrative structures in accordance with the present disclosure. For example, in connection with the described embodiments, a device includes a first structure (e.g., any of the gate structures 108, 2008, and 2408) and a second structure (e.g., any of the S/D contacts 112, 116, 2012, and 2016 or the oxide region 2412). The second structure is separated from the first structure by a cavity (e.g., any of the cavities 120, 124, 2020, 2024, 2420, and 2424). The device further includes a seal material (e.g., any of the seal materials 130, 2030, and 2430) and an etch stop material (e.g., any of the etch stop materials 140, 2036, and 2440) defining an etched region (e.g., any of the etched regions 1802, 1804, 2202, 2204, and 2602). The seal material is configured to seal the cavity. The device further includes a self-aligned contact (SAC) that is formed within the etched region. The SAC adjoins the seal material, the etch stop material, or a combination thereof. For example, the SAC may be any of the SACs 144, 148, 2044, 2048, and 2444, and the etch stop material may be any of the etch stop materials 140, 2036, and 2440. To further illustrate, the SAC 144 adjoins the seal material 130, and the SAC 148 adjoins the etch stop material 140. The SAC 2044 adjoins the etch stop material 2040, and the SAC 2048 adjoins the seal material 2030 and the etch stop material 2036. As an additional example, the SAC 2444 adjoins the seal material 2430 and the etch stop material 2440.

The first structure may be a gate structure (e.g., any of the gate structures 108, 2008, and 2408). The cavity may adjoin the gate structure. For example, the cavities 120, 124 adjoin the gate structure 108, the cavities 2020, 2024 adjoin the gate structure 2008, and the cavities 2420, 2424 adjoin the gate structure 2408. In an example implementation, the SAC is disposed on the gate structure. For example, the SAC 2444 is disposed on the gate structure 2408. In this case, the SAC may be a gate contact.

The second structure may be an S/D contact (e.g., any of the S/D contacts 112, 116, 2012, and 2016). The cavity may adjoin the S/D contact. For example, the cavity 120 adjoins the S/D contact 112, the cavity 124 adjoins the S/D contact 116, the cavity 2020 adjoins the S/D contact 2012, and the cavity 2024 adjoins the S/D contact 2016. In an example implementation, the SAC is disposed on the S/D contact. As illustrative examples, the SAC 144 is disposed on the S/D contact 112, the SAC 148 is disposed on the S/D contact 116, the SAC 2044 is disposed on the S/D contact 2012, and the SAC 2048 is disposed on the S/D contact 2016. In these examples, the SAC may be an S/D contact or a butted contact. In a particular embodiment, the SAC adjoins the gate structure and the S/D contact. For example, the SAC 2048 adjoins the gate structure 2008 and the S/D contact 2016. In this case, the SAC may be a butted contact.

The device may further include a FinFET device that includes the seal material and the SAC. The cavity is formed within the FinFET device. For example, any of the devices 100, 2000, and 2400 may be a FinFET device. In these examples, the cavity may be an air spacer or a vacuum spacer of the FinFET device.

The SAC may be formed in an etched region. The etched region may be defined (e.g., etched out) using a selective etch process that selectively etches a nitride material without substantially etching the seal material. To illustrate, the etched region may correspond to any of the etched regions 1802, 1804, 2202, 2204, and 2602. The nitride material may correspond to any of the etch stop materials 1502, 2104, and 2502.

The device may further include a die (e.g., a semiconductor die). The die may include the seal material and the SAC, and the cavity may be formed within the die. In a particular embodiment, the die is integrated within an electronic device. The electronic device may be selected from a mobile device, a computer, a set top box, an entertainment unit, a navigation device, a personal digital assistant (PDA), a monitor, a television, a tuner, a radio, a music player, a video player, or a combination thereof.

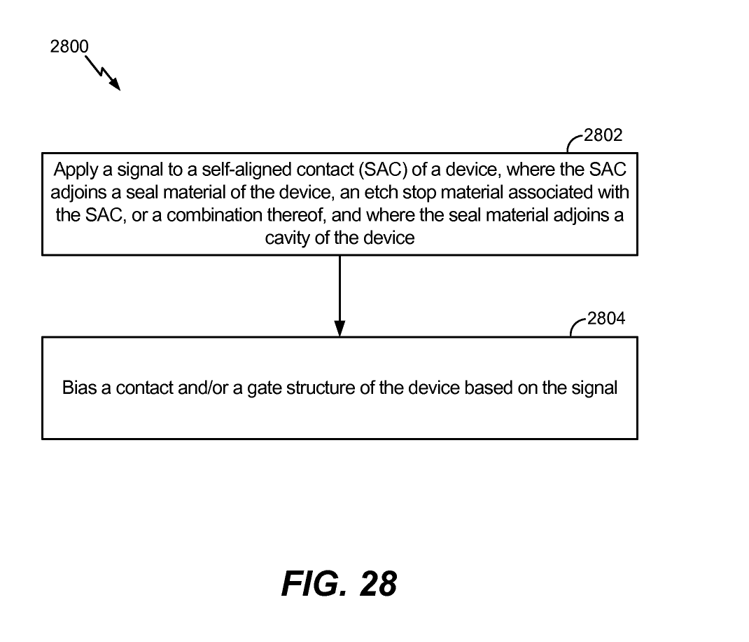

In connection with the described embodiments, an apparatus includes means for sealing a cavity. For example, the means for sealing the cavity may include any of the seal materials 130, 2030, and 2430. The cavity may include any of the cavities 120, 124, 2020, 2024, 2420, and 2424. The apparatus may further include means for defining an etched region and means for conducting a signal. The means for conducting the signal may include a self-aligned contact (SAC) that is formed within the etched region and that adjoins the means for sealing the cavity, the means for defining the etched region, or a combination thereof. For example, the SAC may be any of the SACs 144, 148, 2044, 2048, and 2444, the means for defining the etched region may be any of the etch stop materials 140, 2036, and 2440, and the etched region may be any of the etched regions 1802, 1804, 2202, 2204, and 2602. To further illustrate, the SAC 144 adjoins the seal material 130, and the SAC 148 adjoins the etch stop material 140. The SAC 2044 adjoins the etch stop material 2040, and the SAC 2048 adjoins the seal material 2030 and the etch stop material 2036. As an additional example, the SAC 2444 adjoins the seal material 2430 and the etch stop material 2440. The signal may be generated during operation of a device. An example method of operation of a device is described further with reference to FIG. 28.

Referring to FIG. 28, an illustrative method of operation of a device is depicted and generally designated 2800. The device may correspond to any of the devices 100, 2000, and 2400, as illustrative examples. The device may be a FinFET device.

The method 2800 may include applying a signal to a self-aligned contact (SAC) of the device, at 2802. The SAC adjoins a seal material of the device, an etch stop material associated with the SAC, or a combination thereof. The seal material adjoins a cavity of the device. The signal may be generated by circuitry that includes the device (e.g., by a transistor that is coupled to the device). The SAC may be any of the SACs 144, 148, 2044, 2048, and 2444, as illustrative examples. The seal material may be any of the seal materials 130, 2030, and 2430, and the cavity may be any of the cavities 120, 124, 2020, 2024, 2420, and 2424, as illustrative examples. The etch stop material may be any of the etch stop materials 140, 2036, and 2440.

The method 2800 may further include biasing a contact and/or a gate structure of the device based on the signal, at 2804. To illustrate, applying the signal to the SAC 144 may bias the S/D contact 112, and applying the signal to the SAC 148 may bias the S/D contact 116. As another example, applying the signal to the SAC 2044 may bias the S/D contact 2012, and applying the signal to the SAC 2048 may bias the gate structure 2008 and the S/D contact 2016. As an additional example, applying the signal to the SAC 2444 may bias the gate structure 2408.

The method 2800 of FIG. 28 may improve performance of a device. For example, the cavity of the device may reduce parasitic capacitance during operation of the device as compared to a conventional device that uses a silicon nitride or other material. Reducing parasitic capacitance may improve AC operation, facilitating faster device operation (e.g., faster changes between logical high and logical low states of the device due to reduced capacitive charging and discharging).

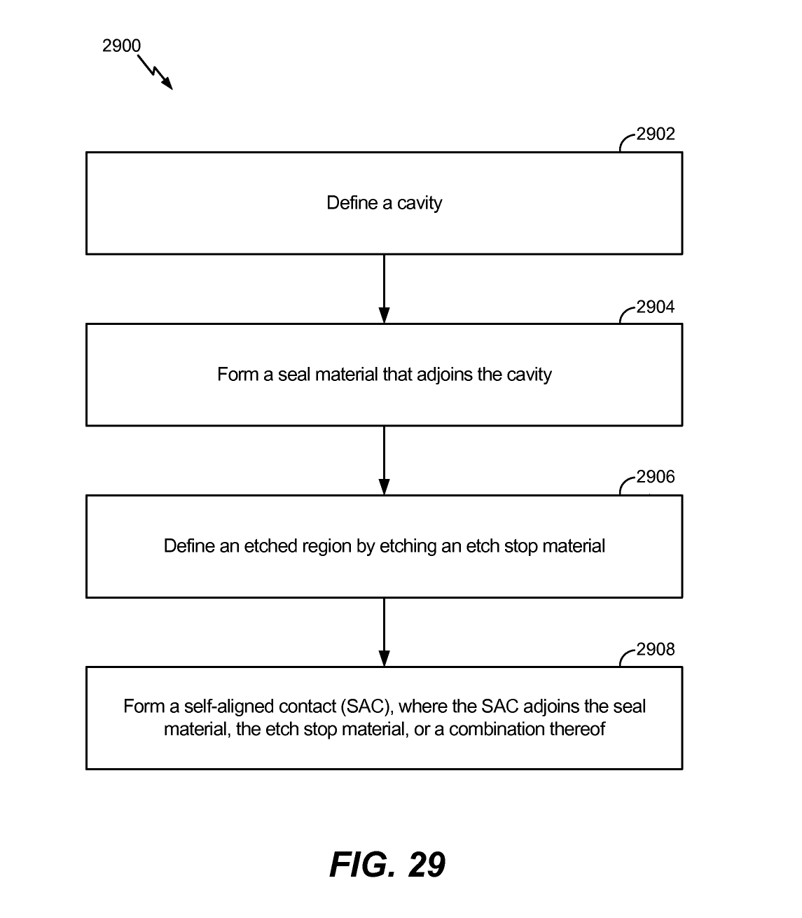

Referring to FIG. 29, an illustrative method of fabrication of a device (e.g., a device) is depicted and generally designated 2900. The device may correspond to any of the devices 100, 2000, and 2400, as illustrative examples. The device may be a FinFET device, such as a FinFET device that is included within a die (e.g., a semiconductor die).

The method 2900 includes defining a cavity, at 2902. The cavity may be defined using an etch process, such as a wet etch or a dry etch, as illustrative examples. To illustrate, the cavity may correspond to any of the cavities 120, 124, 2020, 2024, 2420, and 2424, and the cavity may be defined by removing (e.g., etching out) a sacrificial spacer, such as the sacrificial spacer 402.

The method 2900 further includes forming a seal material, at 2904. The seal material adjoins the cavity. The seal material may be formed using a deposition process, such as a chemical vapor deposition (CVD) process. The seal material may correspond to any of the seal materials 130, 2030, and 2430.

The method 2900 further includes defining (e.g., using an etch process) an etched region by etching an etch stop material, at 2906. For example, the etch stop material may be any of the etch stop materials 140, 2036, and 2440, and the etched region may be any of the etched regions 1802, 1804, 2202, 2204, and 2602, as illustrative examples.

The method 2900 further includes forming (e.g., depositing) a self-aligned contact (SAC) within the etched region, at 2908. The SAC adjoins the seal material, the etch stop material, or a combination thereof. For example, the SAC may correspond to any of the SACs 144, 148, 2044, 2048, and 2444.

In a particular embodiment, the method 2900 further includes forming (e.g., depositing) a C-doped nitride material of prior to forming the SAC. The C-doped nitride material may correspond to any of the etch stop materials 1502, 2104, and 2502. The C-doped nitride material may be etched using an etch process to define the etched region and to define the etch stop layer, and the SAC may be formed within the etched region. To illustrate, the etched region may correspond to any of the etched regions 1802, 1804, 2202, 2204, and 2602. The etch process may selectively etch the C-doped nitride material without substantially etching the seal material.

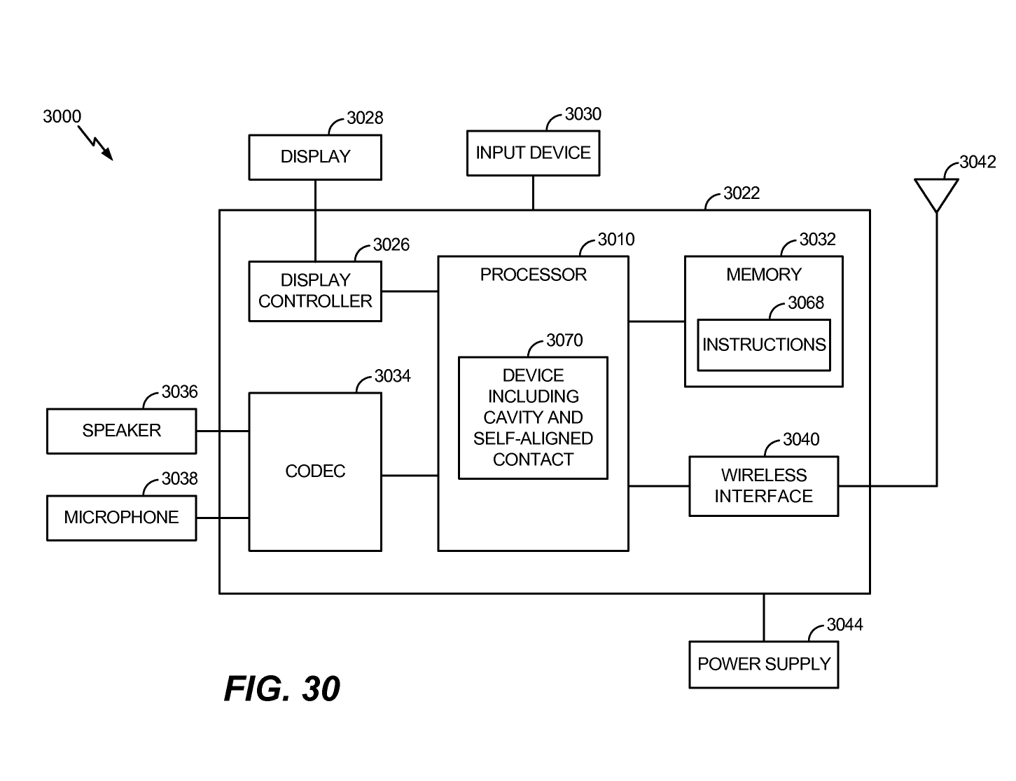

In a particular embodiment, the method 2900 further includes receiving design information representing the device. The design information may have a GDSII file format. The design information may be used to fabricate the device, such as to fabricate a die that includes the device. After fabrication, the die may be incorporated within an electronic device. An example of an electronic device is described further with reference to FIG. 30.

The method 2900 of FIG. 29 enables fabrication of a device that includes a cavity and an SAC. The SAC may reduce or avoid “punch-through” associated with fabrication of the device (e.g., by avoiding etching into the cavity while etching out a region in which the SAC is to be formed).

One or more operations of the method 2900 may be initiated, controlled, or performed by a processing unit. For example, the method 2900 may be implemented by a field-programmable gate array (FPGA) device, an application-specific integrated circuit (ASIC), a processing unit such as a central processing unit (CPU), a digital signal processor (DSP), a controller, another hardware device, a firmware device, or a combination thereof.

Referring to FIG. 30, a block diagram of a particular illustrative embodiment of an electronic device is depicted and generally designated 3000. The electronic device 3000 may correspond to a mobile device or a computer, as illustrative examples.

The electronic device 3000 includes a processor 3010, such as a digital signal processor (DSP). The processor 3010 may include a device 3070 that includes a cavity and a self-aligned contact (SAC). The device 3070 may correspond to any of the devices 100, 2000, and 2400, as illustrative examples.

The electronic device 3000 may further include a memory 3032. The memory 3032 is coupled to the processor 3010. The memory 3032 includes instructions 3068 that are accessible by the processor 3010. The instructions 3068 may include one or more instructions that are executable by the processor 3010. For example, the instructions 3068 may be executable by the processor 3010 to initiate operations of the method 2800 of FIG. 28. To further illustrate, the device 3070 may be a transistor device (e.g., a FinFET device) that is included within a logic device of the processor 3010, such as within an arithmetic and logic unit (ALU). In this example, the processor 3010 may execute the instructions 3068 to initiate certain arithmetic and/or logical operations using the device 3070 (e.g., to add numbers, to multiply numbers, and/or to perform logical operations such as AND, OR, NOT, etc.).

FIG. 30 also shows a display controller 3026 that is coupled to the processor 3010 and to a display 3028. A coder/decoder (CODEC) 3034 can also be coupled to the processor 3010. A speaker 3036 and a microphone 3038 can be coupled to the CODEC 3034. FIG. 30 also indicates that a wireless interface 3040, such as a wireless controller and/or a transceiver, can be coupled to the processor 3010 and to an antenna 3042.

In a particular embodiment, the processor 3010, the display controller 3026, the memory 3032, the CODEC 3034, and the wireless interface 3040 are included in a system-in-package or system-on-chip device 3022. Further, an input device 3030 and a power supply 3044 may be coupled to the system-on-chip device 3022. Moreover, in a particular embodiment, as illustrated in FIG. 30, the display 3028, the input device 3030, the speaker 3036, the microphone 3038, the antenna 3042, and the power supply 3044 are external to the system-on-chip device 3022. However, each of the display 3028, the input device 3030, the speaker 3036, the microphone 3038, the antenna 3042, and the power supply 3044 can be coupled to a component of the system-on-chip device 3022, such as to an interface or to a controller.

Although FIG. 30 illustrates that the device 3070 is included within the processor 3010, it should be appreciated that one or more other components may include a device having a cavity and an SAC. Depending on the application, the device 3070 may be included in another component of the electronic device 3000 that includes a transistor device. For example, the device 3070 may be included in the memory 3032, the wireless interface 3040, the power supply 3044, the input device 3030, the display 3028, the display controller 3026, the CODEC 3034, the speaker 3036, or the microphone 3038.

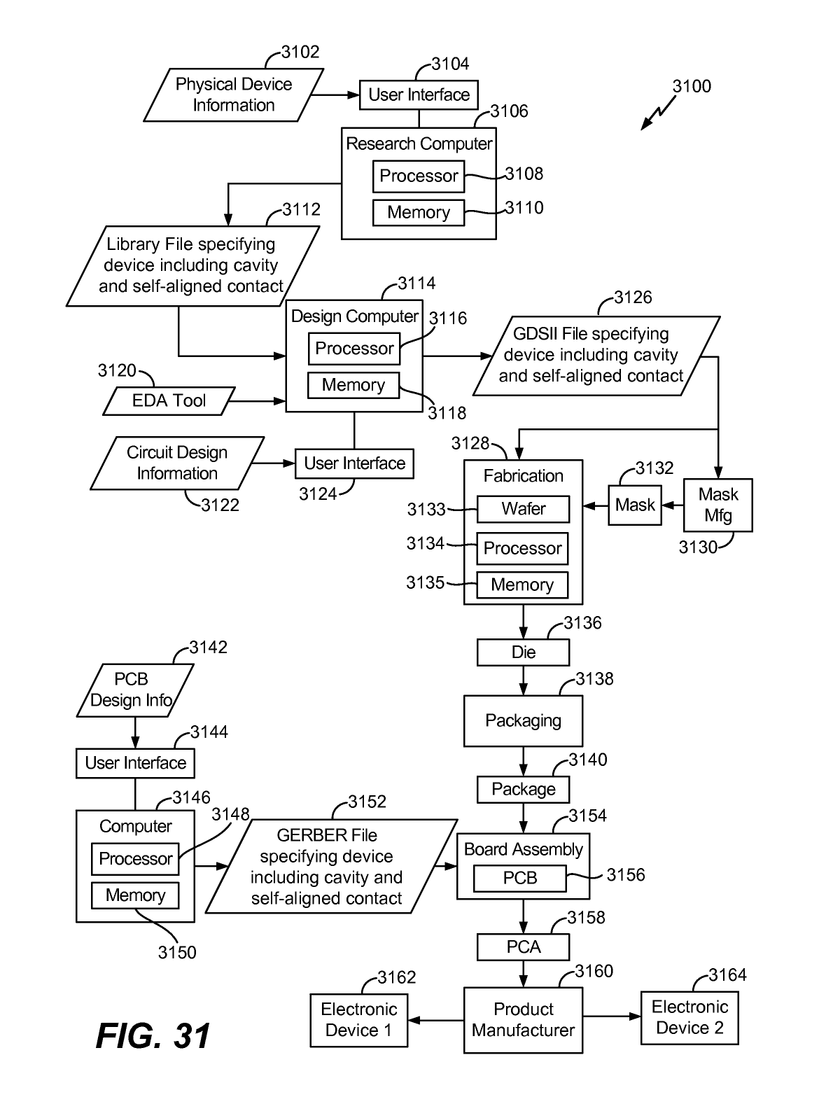

The foregoing disclosed devices and functionalities may be designed and represented using computer files (e.g. RTL, GDSII, GERBER, etc.). The computer files may be stored on computer-readable media. Some or all such files may be provided to fabrication handlers who fabricate devices based on such files. Resulting products include wafers that are then cut into die and packaged into integrated circuits (or “chips”). The chips are then employed in electronic devices, such as the electronic device 3000 of FIG. 30. FIG. 31 depicts a particular illustrative embodiment of an electronic device manufacturing process 3100.

Physical device information 3102 is received at the electronic device manufacturing process 3100, such as at a research computer 3106. The physical device information 3102 may include design information representing at least one physical property of a device, such as one or more of the devices 100, 2000, 2400, and 3070. For example, the physical device information 3102 may include physical parameters, material characteristics, and structure information that is entered via a user interface 3104 coupled to the research computer 3106. The research computer 3106 includes a processor 3108, such as one or more processing cores. The processor 3108 is coupled to a computer-readable medium, such as a memory 3110. The memory 3110 may store computer-readable instructions that are executable by the processor 3108 to transform the physical device information 3102 to comply with a file format and to generate a library file 3112.

The library file 3112 may include at least one data file including the transformed design information. For example, the library file 3112 may specify a library of devices including one or more of the devices 100, 2000, 2400, and 3070.

The library file 3112 may be used in conjunction with an electronic design automation (EDA) tool 3120 at a design computer 3114. The design computer 3114 includes a processor 3116, such as one or more processing cores. The processor 3116 is coupled to a memory 3118. The EDA tool 3120 may include processor executable instructions stored at the memory 3118 to enable a user of the design computer 3114 to design a circuit that includes one or more of the devices 100, 2000, 2400, and 3070. For example, a user of the design computer 3114 may enter circuit design information 3122 via a user interface 3124 coupled to the design computer 3114. The circuit design information 3122 may include design information representing at least one physical property of a device, such as one or more of the devices 100, 2000, 2400, and 3070. To illustrate, the circuit design property may include identification of particular circuits and relationships to other elements in a circuit design, positioning information, feature size information, interconnection information, or other information representing a physical property of a device, such as one or more of the devices 100, 2000, 2400, and 3070.

The design computer 3114 may be configured to transform the circuit design information 3122 to comply with a file format. To illustrate, the file format may include a database binary file format representing planar geometric shapes, text labels, and other information about a circuit layout in a hierarchical format, such as a Graphic Data System (GDSII) file format. The design computer 3114 may be configured to generate a data file including the transformed design information, such as a GDSII file 3126 that includes information describing one or more of the devices 100, 2000, 2400, and 3070.

The GDSII file 3126 may be received at a fabrication process 3128. The fabrication process 3128 may fabricate one or more of the devices 100, 2000, 2400, and 3070 based on the GDSII file 3126. In a particular embodiment, the fabrication process 3128 includes one or more operations of the method 2900 of FIG. 29.

The GDSII file 3126 may be provided to a mask manufacturer 3130 to create one or more masks, such as masks to be used with photolithography processing, illustrated in FIG. 31 as a representative mask 3132. The mask 3132 may be used during the fabrication process 3128 to generate one or more wafers 3133, which may be tested and separated into dies, such as a representative die 3136. The die 3136 may include one or more of the devices 100, 2000, 2400, and 3070.

Operations of the fabrication process 3128 may be initiated or controlled using a processor 3134 and a memory 3135. The memory 3135 may store instructions that are executable by the processor 3134.

The fabrication process 3128 may be implemented by a fabrication system that is fully automated or partially automated. For example, the fabrication process 3128 may be automated according to a schedule. The fabrication system may include fabrication equipment (e.g., processing tools) to perform one or more operations to form a device. For example, the fabrication equipment may be configured to deposit one or more materials, epitaxially grow one or more materials, conformally deposit one or more materials, apply a hardmask, apply an etching mask, perform etching, perform planarization, form a gate stack (e.g., using a metal gate process), perform a shallow trench isolation (STI) process, and/or perform a standard clean 1 process, as illustrative examples.

The fabrication system may have a distributed architecture (e.g., a hierarchy). For example, the fabrication system may include one or more processors, such as the processor 3134, one or more memories, such as the memory 3135, and/or one or more controllers that are distributed according to the distributed architecture. The distributed architecture may include a high-level processor that controls or initiates operations of one or more low-level systems. For example, a high-level portion of the fabrication process 3128 may be initiated or controlled by one or more processors, such as the processor 3134, and the low-level systems may each include or may be controlled by one or more corresponding controllers. A particular controller of a particular low-level system may receive one or more instructions (e.g., commands) from a particular high-level system, may issue sub-commands to subordinate modules or process tools, and may communicate status data back to the high-level processor. Each of the one or more low-level systems may be associated with one or more corresponding pieces of fabrication equipment, such as one or more processing tools. Example processing tools include doping or deposition tools (e.g., a molecular beam epitaxial growth tool, a flowable chemical vapor deposition (FCVD) tool, a conformal deposition tool, or a spin-on deposition tool) and removal tools (e.g., a chemical removal tool, a reactive gas removal tool, a hydrogen reaction removal tool, or a standard clean 1 removal tool).

In a particular embodiment, the fabrication system may include multiple processors that are distributed in the fabrication system. For example, a controller of a low-level system component may include a processor, such as the processor 3134. Alternatively, the processor 3134 may be a part of a high-level system, subsystem, or component of the fabrication system. In another embodiment, the processor 3134 includes distributed processing at various levels and components of a fabrication system.

In connection with the described embodiments, a computer-readable medium (e.g., the memory 3135) stores instructions that are executable by a processor (e.g., the processor 3134) to initiate operations during fabrication of a device. The device may correspond to any of the devices 100, 2000, 2400, and 3070. The operations may include defining a cavity. To illustrate, the cavity may correspond to any of the cavities 120, 124, 2020, 2024, 2420, and 2424, and the cavity may be defined by removing (e.g., etching) a sacrificial spacer, such as the sacrificial spacer 402. The operations may further include forming a seal material. The seal material adjoins the cavity. The seal material may correspond to any of the seal materials 130, 2030, and 2430. The operations may further include defining an etched region by etching an etch stop material and forming a self-aligned contact (SAC) within the etched region. The SAC adjoins the seal material, the etch stop material, or a combination thereof. For example, the SAC may correspond to any of the SACs 144, 148, 2044, 2048, and 2444. The etch stop material may be any of the etch stop materials 140, 2036, and 2440, and the etched region may be any of the etched regions 1802, 1804, 2202, 2204, and 2602, as illustrative examples. The operations may further include fabricating a die that includes the device. The die may correspond to the die 3136.

The die 3136 may be provided to a packaging process 3138. The packaging process 3138 may incorporate the die 3136 into a representative package 3140. The package 3140 may include a single die (such as the die 3136) or multiple dies, such as in connection with a system-in-package (SiP) arrangement. The package 3140 may be configured to conform to one or more standards or specifications, such as one or more Joint Electron Device Engineering Council (JEDEC) standards.

Information regarding the package 3140 may be distributed to various product designers, such as using a component library stored at a computer 3146. The computer 3146 may include a processor 3148, such as one or more processing cores, coupled to a memory 3150. A printed circuit board (PCB) tool may be stored as processor executable instructions at the memory 3150 to process PCB design information 3142 received from a user of the computer 3146 via a user interface 3144. The PCB design information 3142 may include physical positioning information of a packaged device on a circuit board. The packaged device may include one or more of the devices 100, 2000, 2400, and 3070.

The computer 3146 may be configured to transform the PCB design information 3142 to generate a data file, such as a GERBER file 3152. The GERBER file 3152 may indicate physical positioning information of a packaged device on a circuit board, as well as layout of electrical connections, such as traces and vias. The packaged device may include one or more of the devices 100, 2000, 2400, and 3070. In other embodiments, the data file generated by transforming PCB design information 3142 may have a format other than a GERBER format.

The GERBER file 3152 may be received at a board assembly process 3154 and used to create PCBs, such as a representative PCB 3156. The PCB 3156 may be manufactured in accordance with the design information indicated by the GERBER file 3152. For example, the GERBER file 3152 may be uploaded to one or more machines to perform one or more operations of a PCB production process. The PCB 3156 may be populated with electronic components including the package 3140 to form a representative printed circuit assembly (PCA) 3158.

The PCA 3158 may be received at a product manufacture process 3160 and integrated into one or more electronic devices, such as a first representative electronic device 3162 and a second representative electronic device 3164. For example, the first representative electronic device 3162 and/or the second representative electronic device 3164 may include or correspond to the electronic device 3000 of FIG. 30. The first representative electronic device 3162 and/or the second representative electronic device 3164 may include a mobile device (e.g., a cellular telephone), a computer (e.g., a laptop computer, a tablet computer, a notebook computer, or a desktop computer), a set top box, an entertainment unit, a navigation device, a personal digital assistant (PDA), a monitor (e.g., a television monitor or a computer monitor), a television, a tuner, a radio (e.g., a satellite radio), a music player (e.g., a digital music player and/or a portable music player), a video player (e.g., a digital video player, such as a digital video disc (DVD) player and/or a portable digital video player), another electronic device, or a combination thereof.

One or more aspects of the embodiments described with respect to FIGS. 1-31 may be represented by the library file 3112, the GDSII file 3126, and/or the GERBER file 3152. One or more aspects of the embodiments described with respect to FIGS. 1-31 may be represented by information stored at the memory 3110 of the research computer 3106, the memory 3118 of the design computer 3114, the memory 3150 of the computer 3146, and/or a memory of one or more other computers or processors (not shown) used at the various stages, such as at the board assembly process 3154. One or more aspects of the embodiments described with respect to FIGS. 1-31 may be can also be incorporated into one or more other physical embodiments, such as the mask 3132, the die 3136, the package 3140, the PCA 3158, other products such as prototype circuits or devices (not shown), or any combination thereof. Although various representative stages of production from a physical device design to a final product are depicted, in other embodiments fewer stages may be used or additional stages may be included. Similarly, the electronic device manufacturing process 3100 may be performed by a single entity or by one or more entities performing various stages of the electronic device manufacturing process 3100.

Although one or more of FIGS. 1-31 may illustrate systems, apparatuses, and/or methods according to the teachings of the disclosure, the disclosure is not limited to these illustrated systems, apparatuses, and/or methods. One or more functions or components of any of FIGS. 1-31 as illustrated or described herein may be combined with one or more other portions of another of FIGS. 1-31. For example, although the devices 100, 2000, and 2400 are described separately for convenience, it is noted that the devices 100, 2000, and 2400 can be combined (e.g., within a single circuit formed using a common substrate). Accordingly, no single embodiment described herein should be construed as limiting and embodiments of the disclosure may be suitably combined without departing from the teachings of the disclosure.

Those of skill would further appreciate that the various illustrative logical blocks, configurations, modules, circuits, and algorithm steps described in connection with the embodiments disclosed herein may be implemented as electronic hardware, computer software executed by a processor, or combinations of both. Various illustrative components, blocks, configurations, modules, circuits, and steps have been described above generally in terms of their functionality. Whether such functionality is implemented as hardware or processor executable instructions depends upon the particular application and design constraints imposed on the overall system. Skilled artisans may implement the described functionality in varying ways for each particular application, but such implementation decisions should not be interpreted as causing a departure from the scope of the present disclosure.

The steps of a method or algorithm described in connection with the embodiments disclosed herein may be embodied directly in hardware, in a software module executed by a processor, or in a combination of the two. A software module may reside in random access memory (RAM), flash memory, read-only memory (ROM), programmable read-only memory (PROM), erasable programmable read-only memory (EPROM), electrically erasable programmable read-only memory (EEPROM), registers, hard disk, a removable disk, a compact disc read-only memory (CD-ROM), or any other form of non-transitory storage medium known in the art. An exemplary storage medium is coupled to the processor such that the processor can read information from, and write information to, the storage medium. In the alternative, the storage medium may be integral to the processor. The processor and the storage medium may reside in an application-specific integrated circuit (ASIC). The ASIC may reside in a computing device or a user terminal. In the alternative, the processor and the storage medium may reside as discrete components in a computing device or user terminal.

The previous description of the disclosed embodiments is provided to enable a person skilled in the art to make or use the disclosed embodiments. Various modifications to these embodiments will be readily apparent to those skilled in the art, and the principles defined herein may be applied to other embodiments without departing from the scope of the disclosure. Thus, the present disclosure is not intended to be limited to the embodiments shown herein but is to be accorded the widest scope possible consistent with the principles and novel features as defined by the following claims.

What is claimed is:

1. A device comprising:
a first structure;
a second structure separated from the first structure by a cavity;
a seal material configured to seal the cavity;
an etch stop material defining an etched region; and
a self-aligned contact (SAC) formed within the etched region, wherein the SAC adjoins the seal material, the etch stop material, or a combination thereof.

2. The device of claim 1, wherein the seal material includes a silicon oxide material or a carbon-doped silicon oxide material.

3. The device of claim 1, wherein the first structure is a gate structure, wherein the cavity adjoins the gate structure, and wherein the SAC is disposed on the gate structure.

4. The device of claim 1, wherein the second structure is a source or drain (S/D) contact, and wherein the cavity adjoins the S/D contact.

5. The device of claim 4, wherein the SAC is disposed on the S/D contact.

6. The device of claim 4, wherein the first structure is a gate structure, and wherein the SAC adjoins the gate structure and the S/D contact.

7. The device of claim 1, further comprising a fin field-effect transistor (FinFET) device, wherein the FinFET device comprises the seal material and the SAC, and wherein the cavity is formed within the FinFET device.

8. The device of claim 7, wherein the cavity is an air spacer or a vacuum spacer of the FinFET device.

9. The device of claim 1, further comprising a die, wherein the die comprises the seal material and the SAC, and wherein the cavity is formed within the die.

10. The device of claim 9, further comprising an electronic device selected from the group consisting of a mobile device, a computer, a set top box, an entertainment unit, a navigation device, a personal digital assistant (PDA), a monitor, a television, a tuner, a radio, a music player, a video player, or a combination thereof, and wherein the die is integrated within the electronic device.

11. An apparatus comprising:
means for sealing a cavity;
means for defining an etched region; and
means for conducting a signal, wherein the means for conducting the signal includes a self-aligned contact (SAC) formed within the etched region, and wherein the SAC adjoins the means for sealing the cavity, the means for defining the etched region, or a combination thereof.

12. The apparatus of claim 11, further comprising a gate structure, wherein the cavity adjoins the gate structure.

13. The apparatus of claim 12, wherein the SAC is disposed on the gate structure.

14. The apparatus of claim 11, further comprising a source or drain (S/D) contact, wherein the cavity adjoins the S/D contact.

15. The apparatus of claim 14, wherein the SAC is disposed on the S/D contact.

16. The apparatus of claim 11, wherein the means for defining the etched region includes a carbon-doped (C-doped) nitride material, and wherein the etched region is defined using a selective etch process that selectively etches the nitride material without substantially etching the means for sealing the cavity.

17. A method of fabrication of a device, the method comprising:
defining a cavity;
forming a seal material adjoining the cavity;
defining an etched region by etching an etch stop material; and
forming a self-aligned contact (SAC) within the etched region, wherein the SAC adjoins the seal material, the etch stop material, or a combination thereof.

18. The method of claim 17, further comprising, prior to forming the SAC, forming a carbon-doped (C-doped) nitride material, wherein the C-doped nitride material is etched using an etch process to define the etched region and the etch stop material.

19. The method of claim 18, wherein the etch process selectively etches the C-doped nitride material without substantially etching the seal material.

20. The method of claim 17, further comprising receiving design information representing the device, wherein the design information has a GDSII file format.
